(19) United States
(12) Patent Application Publication
(10) Pub. No.: US 2025/0169133 A1
(43) Pub. Date: May 22, 2025

(54) SEMICONDUCTOR DEVICE

(71) Applicant: Samsung Electronics Co., Ltd., Suwon-si (KR)

(72) Inventors: GYEOM KIM, Suwon-si (KR); YOON TAE NAM, Suwon-si (KR); SANG MOON LEE, Suwon-si (KR); KYUNG BIN CHUN, Suwon-si (KR); RYONG HA, Suwon-si (KR); YANG XU, Suwon-si (KR)

(21) Appl. No.: 18/635,282

(22) Filed: Apr. 15, 2024

(30) Foreign Application Priority Data
Nov. 20, 2023 (KR) 10-2023-0160478

(51) Int. Cl. H01L 29/08; H01L 29/06; H01L 29/423; H01L 29/66; H01L 29/775

(52) U.S. Cl. CPC H10D 62/151; H10D 30/014; H10D 30/43; H10D 30/6735; H10D 62/121; H10D 64/017

(57) ABSTRACT

A semiconductor device is provided. The semiconductor device comprises an active pattern extending in a first direction, a plurality of gate structures on the active pattern and spaced apart in the first direction and a source/drain pattern between adjacent ones of the gate structures, wherein the source/drain pattern includes a semiconductor liner film in contact with the active pattern, a lower semiconductor filling film on the semiconductor liner film, an upper semiconductor filling film on the lower semiconductor filling film, and a semiconductor buffer film between the lower semiconductor filling film and the upper semiconductor filling film, each of the semiconductor liner film, the lower semiconductor filling film, the upper semiconductor filling film, and the semiconductor buffer film includes silicon-germanium, a germanium fraction of the semiconductor buffer film is smaller than a germanium fraction of the upper semiconductor filling film and a germanium fraction of the lower semiconductor filling film.

### RELATED APPLICATIONS

This application claims priority from Korean Patent Application No. 10-2023-0160478 filed on Nov. 20, 2023 in the Korean Intellectual Property Office, and all the benefits accruing therefrom under 35 U.S.C. 119, the contents of which in its entirety are herein incorporated by reference.

### BACKGROUND OF THE INVENTION

### 1. Field of the Disclosure

The present disclosure relates to a semiconductor device.

### 2. Description of the Related Art

As one of scaling technologies for increasing density of a semiconductor device, a multi gate transistor in which a multi-channel active pattern (or a silicon body) having a fin or nanowire shape is formed on a substrate and a gate is formed on a surface of the multi-channel active pattern has been proposed.

Since such a multi gate transistor utilizes a three-dimensional channel, scaling is easily performed. Further, even if a gate length of the multi gate transistor is not increased, the current control capability may be improved. Furthermore, a SCE (short channel effect) in which potential of a channel region is influenced by a drain voltage may be effectively suppressed.

### SUMMARY OF THE INVENTION

Aspects of the present disclosure provide a semiconductor device that may improve element performance and reliability.

According to an aspect of the present disclosure, there is provided a semiconductor device comprising an active pattern extending in a first direction, a plurality of gate structures on the active pattern and spaced apart from each other in the first direction and a source/drain pattern between adjacent ones of the gate structures, wherein the source/drain pattern includes a semiconductor liner film in contact with the active pattern, a lower semiconductor filling film on the semiconductor liner film, an upper semiconductor filling film on the lower semiconductor filling film, and a semiconductor buffer film between the lower semiconductor filling film and the upper semiconductor filling film, each of the semiconductor liner film, the lower semiconductor filling film, the upper semiconductor filling film, and the semiconductor buffer film includes silicon-germanium, a germanium fraction of the semiconductor buffer film is smaller than a germanium fraction of the upper semiconductor filling film and a germanium fraction of the lower semiconductor filling film, the semiconductor buffer film and the upper semiconductor filling film are in a lower filling film recess defined by the lower semiconductor filling film, and the semiconductor buffer film extends along a part of the lower filling film recess.

According to an aspect of the present disclosure, there is provided a semiconductor device comprising an active pattern that includes a lower pattern extending in a first direction, and a plurality of sheet patterns spaced apart from the lower pattern in a second direction perpendicular to the first direction, a plurality of gate structures that are on the lower pattern and spaced apart from each other in the first direction, and include a gate electrode and a gate insulating film and a source/drain pattern between adjacent ones of the gate structures, wherein the source/drain pattern includes a semiconductor liner film in contact with the lower pattern and the sheet patterns, a lower semiconductor filling film on the semiconductor liner film, an upper semiconductor filling film on the lower semiconductor filling film, and a semiconductor buffer film between the lower semiconductor filling film and the upper semiconductor filling film, the semiconductor liner film, the lower semiconductor filling film, the upper semiconductor filling film, and the semiconductor buffer film each include silicon-germanium, a germanium fraction of the semiconductor buffer film is smaller than a germanium fraction of the upper semiconductor filling film and a germanium fraction of the lower semiconductor filling film, the semiconductor buffer film extends along a profile of a lower filling film recess defined by the lower semiconductor filling film, the semiconductor buffer film includes a bottom portion, and a side portion extending in the second direction from the bottom portion, and a germanium fraction of the side portion is different from a germanium fraction of the bottom portion.

According to an aspect of the present disclosure, there is provided a semiconductor device comprising an active pattern that includes a lower pattern extending in a first direction, and a plurality of sheet patterns spaced apart from the lower pattern in a second direction perpendicular to the first direction, a plurality of gate structures that are on the lower pattern and spaced apart from each other in the first direction, and include a gate electrode and a gate insulating film and a source/drain pattern between adjacent ones of the gate structures, wherein the source/drain pattern includes a semiconductor liner film in contact with the lower pattern and the sheet patterns, a lower semiconductor filling film on the semiconductor liner film, an upper semiconductor filling film on the lower semiconductor filling film, and a semiconductor buffer film between the lower semiconductor filling film and the upper semiconductor filling film, the semiconductor liner film, the lower semiconductor filling film, the upper semiconductor filling film, and the semiconductor buffer film each include silicon-germanium, a germanium fraction of the semiconductor buffer film is smaller than a germanium fraction of the upper semiconductor filling film and a germanium fraction of the lower semiconductor filling film, the semiconductor buffer film extends along a profile of a lower filling film recess defined by the lower semiconductor filling film, the semiconductor buffer film includes a bottom portion, and a side portion extending in the second direction from the bottom portion, and a thickness of the side portion is greater than a thickness of the bottom portion.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

FIG. 1 is an example plan view of a semiconductor device according to some embodiments.

FIGS. 2 and 3 are cross-sectional views taken along lines A-A and B-B, respectively, of FIG. 1.

FIGS. 4 to 7 are diagrams schematically showing a germanium fraction along a SCAN LINE of FIG. 2.

FIG. 8 is a cross-sectional view taken along A-A of FIG. 1.

FIG. 9 is a diagram for explaining the germanium fraction of the first lower semiconductor filling film and the first upper semiconductor filling film.

FIG. 10 is a cross-sectional diagram for explaining a semiconductor device according to some embodiments.

FIG. 11 is a cross-sectional view taken along a line A-A of FIG. 1.

FIG. 12 is a cross-sectional diagram for explaining the shape of the first semiconductor buffer film of FIG. 11.

FIGS. 13 and 14 are diagrams for explaining the germanium fraction of the first semiconductor buffer film, the first lower semiconductor filling film, and the first upper semiconductor filling film.

FIGS. 15 to 17 are cross-sectional diagrams for explaining a semiconductor device according to some embodiments.

FIG. 18 is a cross-sectional diagram for explaining a semiconductor device according to some embodiments.

FIGS. 19 to 21 are cross-sectional diagrams for explaining a semiconductor device according to some embodiments.

FIGS. 22 and 23 are cross-sectional diagrams for explaining a semiconductor device according to some embodiments.

FIG. 24 is an example plan view for explaining a semiconductor device according to some embodiments.

FIG. 25 is a cross-sectional view taken along a line A-A of FIG. 24.

FIG. 26 is a cross-sectional view taken along a line C-C of FIG. 24.

FIGS. 27 to 36 are intermediate step diagrams for explaining a method for fabricating a semiconductor device according to some embodiments.

### DETAILED DESCRIPTION

Although drawings of a semiconductor device according to some embodiments show a fin-type transistor (FinFET) including a channel region of a fin-type pattern shape, a transistor including a nanowire or a nanosheet, and a MBCFET™ (Multi-Bridge Channel Field Effect Transistor) as an example, embodiments herein are not limited thereto. The semiconductor device according to some embodiments may, of course, include a tunneling transistor (tunneling FET) or a three-dimensional (3D) transistor. The semiconductor device according to some embodiments may, of course, include a planar transistor. In addition, some embodiments of the present disclosure may be applied to a transistor based on a two-dimensional material (2D material based FETs) and a heterostructure thereof.

Further, the semiconductor device according to some embodiments may also include a bipolar junction transistor, a laterally diffused metal oxide semiconductor (LDMOS), or the like.

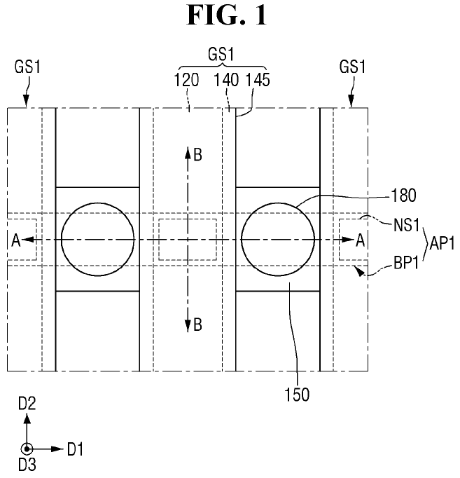

The semiconductor device according to some embodiments will be described with reference to FIGS. 1 to 7.

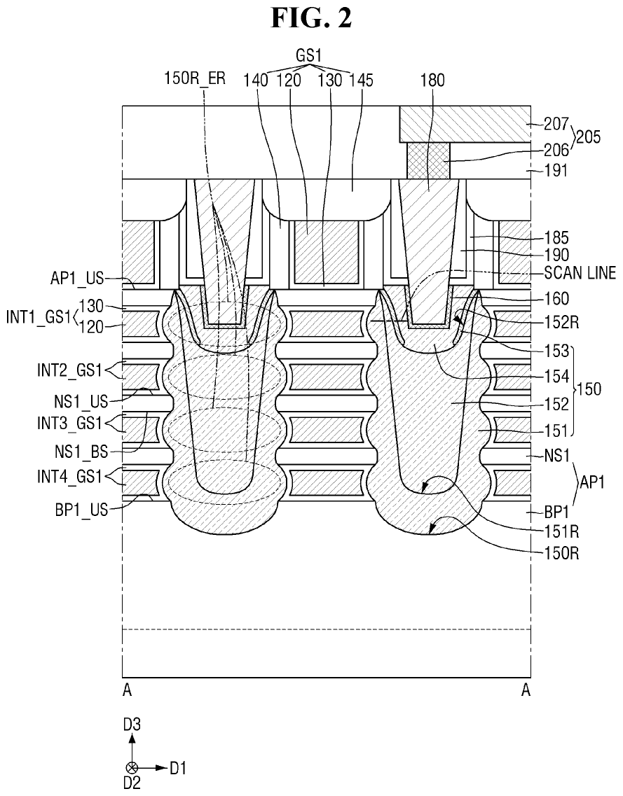

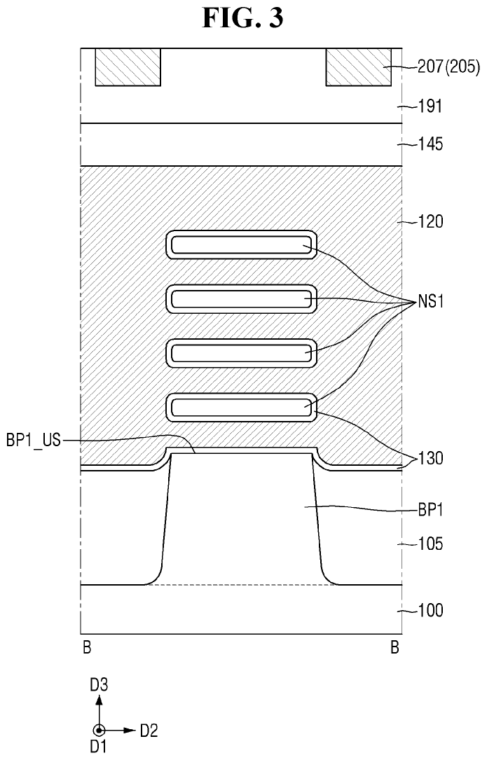

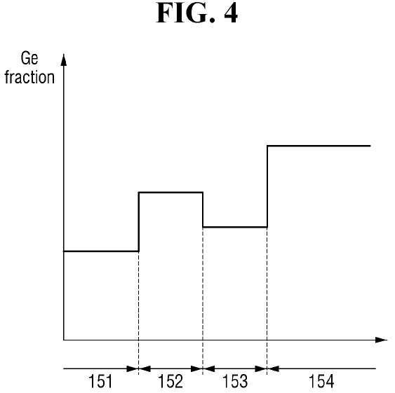

FIG. 1 is an example plan view for explaining the semiconductor device according to some embodiments. FIGS. 2 and 3 are cross-sectional views taken along lines A-A and B-B of FIG. 1. FIGS. 4 to 7 are diagrams schematically showing a germanium fraction along a SCAN LINE of FIG. 2, respectively.

For reference, FIG. 1 is simply shown except for a first gate insulating film 130 (FIG. 2), a source/drain etching stop film 185 (FIG. 2), an interlayer insulating film 190 (FIG. 2), a wiring structure 205 (FIG. 3), and the like, which are omitted from view in FIG. 1 for simplicity of illustration. Further, a position of SCAN LINE of FIG. 2 may be an arbitrary position.

Referring to FIGS. 1 to 7, the semiconductor device according to some embodiments may include a first active pattern AP1, a plurality of first gate structures GS1, and a first source/drain pattern 150 that are on a substrate 100.

The substrate 100 may be bulk silicon or silicon-on-insulator (SOI) in some embodiments. In other embodiments, the substrate 100 may be a silicon substrate, or may include, but is not limited to, other materials, for example, silicon germanium, SGOI (silicon germanium on insulator), indium antimonide, lead tellurium compounds, indium arsenic, indium phosphide, gallium arsenide, or gallium antimonide.

A first active pattern AP1 may be disposed on the substrate 100. The first active pattern AP1 may extend long in a first direction D1.

As an example, the first active pattern AP1 may be disposed in a region in which a PMOS transistor/device is formed. As another example, the first active pattern AP1 may be disposed in a region in which an NMOS transistor/device is formed. In the following description, it will be described that the first active pattern AP1 is disposed in a region in which a PMOS transistor/device is formed. When the first active pattern AP1 is disposed in the region in which the NMOS transistor/device is formed, related contents will be briefly described in the following description.

The first active pattern AP1 may be, for example, a multi-channel active pattern. The first active pattern AP1 may include a first lower pattern BP1 and a plurality of first sheet patterns NS1.

The first lower pattern BP1 may protrude from the substrate 100. The first lower pattern BP1 may extend long in the first direction D1.

The plurality of first sheet patterns NS1 may be disposed on an upper surface BP1_US of the first lower pattern BP1. The plurality of first sheet patterns NS1 may be spaced apart from the first lower pattern BP1 in a third direction D3. Each first sheet pattern NS1 may be spaced apart from the other first sheet patterns NS1 in the third direction D3.

Each first sheet pattern NS1 may include an upper surface NS1_US and a lower surface NS1_BS. The upper surface NS1_US of the first sheet pattern is opposite to the lower surface NS1_BS of the first sheet pattern in the third direction D3. The third direction D3 may be a direction that intersects the first direction D1 and a second direction D2. For example, each of the first direction D1 and the second direction D2 may be perpendicular to the third direction D3. The third direction D3 may be a thickness direction of the substrate 100. The first direction D1 may be a direction that intersects the second direction D2. For example, the first direction D1 may be perpendicular to the second direction D2.

Although four first sheet patterns NS1 are shown as being disposed in the third direction D3, this example is only for convenience of explanation and the present disclosure is not limited thereto. The upper surface NS1_US of the first sheet pattern NS1 may be an upper surface of the first sheet pattern NS1 disposed at the uppermost part of the plurality of first sheet patterns NS1.

The first lower pattern BP1 may be formed by etching a part of the substrate 100, or may include an epitaxial layer grown from the substrate 100. The first lower pattern BP1 may include silicon or germanium, which is an elemental semiconductor material. Also, the first lower pattern BP1 may include a compound semiconductor, and may include, for example, a group IV-IV compound semiconductor or a group III-V compound semiconductor.

The group IV-IV compound semiconductor may be, for example, a binary compound or a ternary compound including at least two or more of carbon (C), silicon (Si), germanium (Ge) and tin (Sn), or a compound obtained by doping these elements with a group IV element.

The group III-V compound semiconductor may be, for example, one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

The first sheet pattern NS1 may include one of silicon or germanium, which is an elemental semiconductor material, a group IV-IV compound semiconductor, or a group III-V compound semiconductor. Each first sheet pattern NS1 may include the same material as the first lower pattern BP1, or may include a material different from the first lower pattern BP1.

In the semiconductor device according to some embodiments, the first lower pattern BP1 may be a silicon lower pattern including silicon, and the first sheet pattern NS1 may be a silicon sheet pattern including silicon.

A width of the first sheet pattern NS1 in the second direction D2 may increase or decrease in proportion to a width of the first lower pattern BP1 in the second direction D2. As an example, although the first sheet patterns NS1 stacked in the third direction D3 are shown to have the same width in the second direction D2, this example is only for convenience of explanation and the present disclosure is not limited thereto. Unlike the shown example, the width in the second direction D2 of the first sheet patterns NS1 stacked in the third direction D3 may decrease, as the first sheet patterns NS1 go away from the first lower pattern BP1.

A field insulating film 105 may be formed on the substrate 100. The field insulating film 105 may be disposed on the side walls of the first lower pattern BP1. The field insulating film 105 is not disposed on the upper surface BP1_US of the first lower pattern BP1.

As an example, the field insulating film 105 may entirely cover the side walls of the first lower pattern BP1. Unlike the shown example, the field insulating film 105 may cover only a part of the side walls of the first lower pattern BP1. In such a case, a part of the first lower pattern BP1 may protrude from the upper surface of the field insulating film 105 in the third direction D3.

Each first sheet pattern NS1 is disposed to be higher than the upper surface of the field insulating film 105. The field insulating film 105 may include, for example, an oxide film, a nitride film, an oxynitride film or a combined film thereof. Although the field insulating film 105 is shown as being a single film, this example is only for convenience of explanation and the present disclosure is not limited thereto.

A plurality of first gate structures GS1 may be disposed on the substrate 100. Each first gate structure GS1 may extend in the second direction D2. The first gate structures GS1 may be spaced apart from each other in the first direction D1. The first gate structures GS1 may be adjacent to each other in the first direction D1. For example, the first gate structure GS1 may be disposed on both (i.e., opposite) sides of the first source/drain pattern 150 in the first direction D1.

The first gate structure GS1 may be disposed on the first active pattern AP1. The first gate structure GS1 may intersect the first active pattern AP1.

The first gate structure GS1 may intersect the first lower pattern BP1. The first gate structure GS1 may wrap around each of the first sheet patterns NS1.

The first gate structure GS1 may include, for example, a first gate electrode 120, a first gate insulating film 130, a first gate spacer 140, and a first gate capping pattern 145.

The first gate structure GS1 may include a plurality of inner gate structures INT1_GS1, INT2_GS1, INT3_GS1 and INT4_GS1 disposed between the first sheet patterns NS1 adjacent to each other in the third direction D3, and between the first lower pattern BP1 and the first sheet pattern NS1. The inner gate structures INT1_GS1, INT2_GS1, INT3_GS1 and INT4_GS1 may be disposed between the upper surface BP1_US of the first lower pattern BP1 and the lower surface NS1_BS of the first sheet pattern NS1, and between the upper surface NS1_US of the first sheet pattern NS1 and the lower surface NS1_BS of the first sheet pattern NS1 facing each other in the third direction D3.

The number of inner gate structures INT1_GS1, INT2_GS1, INT3_GS1 and INT4_GS1 may be proportional to the number of first sheet patterns NS1 included in the first active pattern AP1. For example, the number of (e.g., four) inner gate structures INT1_GS1, INT2_GS1, INT3_GS1 and INT4_GS1 may be the same as the number of first sheet patterns NS1. Since the first active pattern AP1 includes a plurality of first sheet patterns NS1, the first gate structure GS1 may include a plurality of inner gate structures.

The inner gate structures INT1_GS1, INT2_GS1, INT3_GS1 and INT4_GS1 are in contact with the upper surface BP1_US of the first lower pattern BP1, the upper surface NS1_US of the first sheet pattern NS1, and the lower surface NS1_BS of the first sheet pattern NS1. As used herein, the term “contact” refers to direct, physical contact.

In the semiconductor device according to some embodiments, the inner gate structures INT1_GS1, INT2_GS1, INT3_GS1 and INT4_GS1 may be in contact with a first source/drain pattern 150 which will be described below. For example, the inner gate structures INT1_GS1, INT2_GS1, INT3_GS1 and INT4_GS1 may be in direct contact with the first source/drain pattern 150.

The following description will be provided, using a case in which the number of inner gate structures INT1_GS1, INT2_GS1, INT3_GS1 and INT4_GS1 is four.

The first gate structure GS1 may include a first inner gate structure INT1_GS1, a second inner gate structure INT2_GS1, a third inner gate structure INT3_GS1, and a fourth inner gate structure INT4_GS1. The first inner gate structure INT1_GS1, the second inner gate structure INT2_GS1, the third inner gate structure INT3_GS1 and the fourth inner gate structure INT4_GS1 may be sequentially disposed on the first lower pattern BP1.

The fourth inner gate structure INT4_GS1 may be disposed between the first lower pattern BP1 and the first sheet pattern NS1. The fourth inner gate structure INT4_GS1 may be disposed at the lowermost level/part among the inner gate structures INT1_GS1, INT2_GS1, INT3_GS1 and INT4_GS1. The fourth inner gate structure INT4_GS1 may be the lowermost inner gate structure.

The first inner gate structure INT1_GS1, the second inner gate structure INT2_GS1 and the third inner gate structure INT3_GS1 may be disposed between the first sheet patterns NS1 adjacent to each other in the third direction D3. The first inner gate structure INT1_GS1 may be disposed at the uppermost level/part among the inner gate structures INT1_GS1, INT2_GS1, INT3_GS1 and INT4_GS1. The first inner gate structure INT1_GS1 may be an uppermost inner gate structure. The second inner gate structure INT2_GS1 and the third inner gate structure INT3_GS1 are disposed between the first inner gate structure INT1_GS1 and the fourth inner gate structure INT4_GS1.

The inner gate structures INT1_GS1, INT2_GS1, INT3_GS1 and INT4_GS1 include a first gate electrode 120 and a first gate insulating film 130 disposed between adjacent first sheet patterns NS1, and between the first lower pattern BP1 and the first sheet pattern NS1.

The following description will be provided on the basis of FIG. 2, which is a cross-sectional view taken in the first direction D1. As an example, the width of the first inner gate structure INT1_GS1 may be the same as the width of the second inner gate structure INT2_GS1 and the width of the third inner gate structure INT3_GS1. The width of the fourth inner gate structure INT4_GS1 may be the same as the width of the third inner gate structure INT3_GS1.

As another example, the width of the fourth inner gate structure INT4_GS1 may be greater than the width of the third inner gate structure INT3_GS1. The width of the first inner gate structure INT1_GS1 may be the same as the width of the second inner gate structure INT2_GS1 and the width of the third inner gate structure INT3_GS1.

The second inner gate structure INT2_GS1 will be described as an example. The width of the second inner gate structure INT2_GS1 may be measured in the middle between the upper surface NS1_US of the first sheet pattern NS1 and the lower surface NS1_BS of the first sheet pattern NS1 that face each other in the third direction D3.

The first gate electrode 120 may be formed on the first lower pattern BP1. The first gate electrode 120 may intersect the first lower pattern BP1. The first gate electrode 120 may wrap around the first sheet pattern NS1.

A part of the first gate electrode 120 may be disposed between the first sheet patterns NS1 adjacent to each other in the third direction D3. When the first sheet pattern NS1 includes a first lower sheet pattern and a first upper sheet pattern adjacent to each other in the third direction D3, a part of the first gate electrode 120 may be disposed between the upper surface NS1_US of the first lower sheet pattern and the lower surface NS1_BS of the first upper sheet pattern that face each other. Also, a part of the first gate electrode 120 may be disposed between the upper surface BS1_US of the first lower pattern BS1 and the lower surface NS1_BS of the first lowermost sheet pattern.

The first gate electrode 120 may include at least one of metal, metal alloy, conductive metal nitride, metal silicide, doped semiconductor material, conductive metal oxide and conductive metal oxynitride. The first gate electrode 120 may include, but is not limited to, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAIC-N), titanium aluminum carbide (TiAIC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxide and conductive metal oxynitride may include, but are not limited to, oxidized forms of the aforementioned materials.

The first gate electrode 120 may be disposed on both (i.e., opposite) sides of a first source/drain pattern 150, which will be described below. The first gate structure GS1 may be disposed on both sides of the first source/drain pattern 150 in the first direction D1.

As an example, both the first gate structures GS1 disposed on both sides of the first source/drain pattern 150 may be normal gate electrodes used as gates of transistors. As another example, the first gate electrode 120 disposed on one side of the first source/drain pattern 150 may be used as a gate of a transistor, but the first gate electrode 120 disposed on the other side of the first source/drain pattern 150 may be a dummy gate electrode.

The first gate insulating film 130 may extend along the upper surface of the field insulating film 105 and the upper surface BP1_US of the first lower pattern BP1. The first gate insulating film 130 may wrap around the plurality of first sheet patterns NS1. The first gate insulating film 130 may be disposed along the periphery of the first sheet pattern NS1. The first gate electrode 120 is disposed on the first gate insulating film 130. The first gate insulating film 130 is disposed between the first gate electrode 120 and the first sheet pattern NS1. A part of the first gate insulating film 130 may be disposed between the first sheet patterns NS1 adjacent in the third direction D3, and between the first lower pattern BP1 and the first sheet pattern NS1.

The first gate insulating film 130 may include silicon oxide, silicon-germanium oxide, germanium oxide, silicon oxynitride, silicon nitride, or a high dielectric constant material having a higher dielectric constant than silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Although the first gate insulating film 130 is shown as being a single film, this example is only for convenience of explanation and the present disclosure is not limited thereto. The first gate insulating film 130 may include multiple films. The first gate insulating film 130 may include an interfacial layer disposed between the first sheet pattern NS1 and the first gate electrode 120, and a high dielectric constant insulating film.

The semiconductor device according to some embodiments may include an NC (Negative Capacitance) FET that uses a negative capacitor. For example, the first gate insulating film 130 may include a ferroelectric material film having ferroelectric properties, and a paraelectric material film having paraelectric properties.

The ferroelectric material film may have a negative capacitance, and the paraelectric material film may have a positive capacitance. For example, when two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, but is not limited to, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness having the ferroelectric properties. The thickness of the ferroelectric material film may be, for example, but is not limited to, 0.5 to 10 nanometers (nm). Since a critical thickness that exhibits the ferroelectric properties may vary for each ferroelectric material, the thickness of the ferroelectric material film may vary depending on the ferroelectric material.

As an example, the first gate insulating film 130 may include a single ferroelectric material film. As another example, the first gate insulating film 130 may include a plurality of ferroelectric material films spaced apart from each other. The first gate insulating film 130 may have a stacked film structure in which the plurality of ferroelectric material films and the plurality of paraelectric material films are alternately stacked.

The first gate spacer 140 may be disposed on the side wall of the first gate electrode 120. The first gate spacer 140 may not be disposed between the first lower pattern BP1 and the first sheet pattern NS1, and between the first sheet patterns NS1 adjacent in the third direction D3. In the semiconductor device according to some embodiments, the first gate spacer 140 may include only an outer spacer.

The first gate spacer 140 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. Although the first gate spacer 140 is shown as being a single film, this example is only for convenience of explanation and the present disclosure is not limited thereto.

A first gate capping pattern 145 may be disposed on the first gate electrode 120 and the first gate spacer 140. An upper surface of the first gate capping pattern 145 may be disposed on the same plane as an upper surface of the first interlayer insulating film 190. The first gate capping pattern 145 may be disposed between the first gate spacers 140, unlike the shown example.

The first gate capping pattern 145 may include, for example, at least one of silicon nitride (SiN), silicon oxynitride (SiON), silicon carbonitride (SiCN), silicon oxycarbonitride (SiOCN), and combinations thereof. The first gate capping pattern 145 may include a material having an etching selectivity with respect to the interlayer insulating film 190.

A first source/drain pattern 150 may be formed on the first active pattern AP1. The first source/drain pattern 150 may be disposed on the first lower pattern BP1. The first source/drain pattern 150 is electrically connected to the first sheet pattern NS1. The first source/drain pattern 150 comes into contact with the first sheet pattern NS1.

The first source/drain pattern 150 may be disposed on the side face of the first gate structure GS1. The first source/drain pattern 150 may be disposed between the first gate structures GS1 adjacent to each other in the first direction D1. For example, the first source/drain patterns 150 may be disposed on both (i.e., opposite) sides of the first gate structure GS1. Unlike the shown example, the first source/drain pattern 150 may be disposed on one side of the first gate structure GS1 and not disposed on the other side of the first gate structure GS1.

The first source/drain pattern 150 may be included in a source/drain of a transistor that uses the first sheet pattern NS1 as a channel region.

The first source/drain pattern 150 may be disposed inside a first source/drain recess 150R. The first source/drain pattern 150 may fill the source/drain recess 150R.

The first source/drain recess 150R extends in the third direction D3. The first source/drain recess 150R may be defined between the first gate structures GS1 adjacent to each other in the first direction D1.

A lower surface of the first source/drain recess 150R is defined by the first lower pattern BP1. The side walls of the first source/drain recess 150R may be defined by the first sheet pattern NS1 and the inner gate structures INT1_GS1, INT2_GS1, INT3_GS1 and INT4_GS1.

The inner gate structures INT1_GS1, INT2_GS1, INT3_GS1 and INT4_GS1 may include upper surfaces that face the lower surface NS1_BS of the first sheet pattern. The inner gate structures INT1_GS1, INT2_GS1, INT3_GS1 and INT4_GS1 include lower surfaces that face the upper surface NS1_US of the first sheet pattern or the upper surface BP1_US of the first lower pattern. The inner gate structures INT1_GS1, INT2_GS1, INT3_GS1 and INT4_GS1 include side walls that connect the upper surfaces of the inner gate structures INT1_GS1, INT2_GS1, INT3_GS1 and INT4_GS1 and the lower surfaces of the inner gate structures INT1_GS1, INT2_GS1, INT3_GS1 and INT4_GS1. The side walls of the inner gate structures INT1_GS1, INT2_GS1, INT3_GS1 and INT4_GS1 may define a part of the side walls of the first source/drain recess 150R.

Between the first sheet pattern NS1 disposed at the lowermost part and the first lower pattern BP1, a boundary between the first gate insulating film 130 and the first lower pattern BP1 may be an upper surface BP1_US of the first lower pattern. The upper surface BP1_US of the first lower pattern BP1 may be a boundary between the fourth inner gate structure INT4_GS1 and the first lower pattern BP1. A lower surface of the first source/drain recess 150R is lower than the upper surface BP1_US of the first lower pattern BP1.

Side walls of the first source/drain recess 150R may have a wavy shape. The first source/drain recess 150R may include a plurality of first width extension regions 150R_ER. Each of the first width extension regions 150R_ER may be defined above the upper surface BP1_US of the first lower pattern.

The first width extension region 150R_ER may be defined between the first sheet patterns NS1 adjacent to each other in the third direction D3. The first width extension region 150R_ER may be defined between the first lower pattern BP1 and the first sheet pattern NS1. The first width extension region 150R_ER may extend between the first sheet patterns NS1 adjacent to each other in the third direction D3. The first width extension region 150R_ER may be defined between the inner gate structures INT1_GS1, INT2_GS1, INT3_GS1 and INT4_GS1 adjacent to each other in the first direction D1.

Each of the first width extension regions 150R_ER may include a portion whose width in the first direction D1 increases and a portion whose width in the first direction D1 decreases, as it goes away from the upper surface BP1_US of the first lower pattern. For example, the width of the first width extension region 150R_ER may increase and then decrease, as it goes away from the upper surface BP1_US of the first lower pattern.

In each of the first width extension regions 150R_ER, a point on which the first width extension region 150R_ER has the maximum width is located between the first sheet pattern NS1 and the first lower pattern BP1, or between the first sheet patterns NS1 adjacent to each other in the third direction D3.

The first source/drain pattern 150 may be in direct contact with the first lower pattern BP1. The first gate insulating films 130 of the inner gate structures INT1_GS1, INT2_GS1, INT3_GS1 and INT4_GS1 may be in contact with the first source/drain pattern 150.

The first source/drain pattern 150 may include a semiconductor liner film 151, a first lower semiconductor filling film 152, a first semiconductor buffer film 153, and a first upper semiconductor filling film 154.

The first semiconductor liner film 151 may be continuously formed along the first source/drain recess 150R. The first semiconductor liner film 151 may extend along the side walls of the first source/drain recess 150R and the lower surface of the first source/drain recess 150R. The first semiconductor liner film 151 formed along the first source/drain recess 150R defined by the first sheet pattern NS1 is directly connected to (i.e., in contact with) the first semiconductor liner film 151 formed along the first source/drain recess 150R defined by the inner gate structures INT1_GS1, INT2_GS1, INT3_GS1 and INT4_GS1.

The first semiconductor liner film 151 may be in contact with the first sheet pattern NS1 (of the first active pattern AP1), the first lower pattern BP1 (of the first active pattern AP1), and the inner gate structures INT1_GS1, INT2_GS1, INT3_GS1 and INT4_GS1 (of the first gate structure GS1). The first semiconductor liner film 151 may be in contact with the first gate insulating films 130 of the inner gate structures INT1_GS1, INT2_GS1, INT3_GS1 and INT4_GS1.

The first semiconductor liner film 151 may include an outer side face and an inner side face. The outer side face of the first semiconductor liner film 151 may be in contact with the first gate insulating film 130, the first sheet pattern NS1 and the first lower pattern BP1. The outer side face of the first semiconductor liner film 151 may be in contact with the side walls of the inner gate structures INT1_GS1, INT2_GS1, INT3_GS1 and INT4_GS1. The outer side face of the first semiconductor liner film 151 may exhibit the profile of the first source/drain recess 150R.

The inner side face of the first semiconductor liner film 151 may be opposite to the outer side face of the first semiconductor liner film 151. The inner side face of the first semiconductor liner film 151 may face the semiconductor filling film 153.

The first semiconductor liner film 151 may define a first liner recess 151R. For example, the first liner recess 151R may be defined by the inner side face of the first semiconductor liner film 151. For example, the width of the first liner recess 151R in the first direction D1 may increase as it goes away from the first lower pattern BP1. Unlike the shown example, the side walls of the first liner recess 151R may have a wavy shape similar to the side walls of the first source/drain recess 150R. The first lower semiconductor filling film 152, the first upper semiconductor filling film 154, and the first semiconductor buffer film 153 may be disposed inside the first liner recess 151R.

The first lower semiconductor filling film 152 may be disposed on the first semiconductor liner film 151. The first lower semiconductor filling film 152 may partially fill the first liner recess 151R.

The first lower semiconductor filling film 152 may include an outer side face and an inner side face. The outer side face of the first lower semiconductor filling film 152 may face the first semiconductor liner film 151.

The inner side face of the first lower semiconductor filling film 152 may be opposite to the outer side face of the first lower semiconductor filling film 152. The inner side face of the first lower semiconductor filling film 152 may face the first upper semiconductor filling film 154.

The first lower semiconductor filling film 152 may define a first lower filling film recess 152R. For example, the first lower filling film recess 152R may be defined by the inner side face of the first lower semiconductor filling film 152. For example, the width of the first lower filling film recess 152R in the first direction D1 may increase, as it goes away from the first lower pattern BP1.

The first upper semiconductor filling film 154 may be disposed on the first lower semiconductor filling film 152. The first lower semiconductor filling film 152 may be disposed between the first upper semiconductor filling film 154 and the first semiconductor liner film 151.

The first semiconductor buffer film 153 may be disposed on the first lower semiconductor filling film 152. The first semiconductor buffer film 153 may be disposed between the first lower semiconductor filling film 152 and the first upper semiconductor filling film 154. The first semiconductor buffer film 153 and the first upper semiconductor filling film 154 may be in (e.g., may fill) the first lower filling film recess 152R.

In the semiconductor device according to some embodiments, the first semiconductor buffer film 153 may extend along a part of the first lower filling film recess 152R. For example, the first semiconductor buffer film 153 may extend along at least a part of the side portion/wall of the first lower filling film recess 152R. The first semiconductor buffer film 153 may not extend along the lower portion/surface of the first lower filling film recess 152R. For example, the side portion/wall of the first lower filling film recess 152R may extend in the third direction D3.

From a cross-sectional point of view, a pair of first semiconductor buffer films 153 separated from each other may be disposed between the first lower semiconductor filling film 152 and the first upper semiconductor filling film 154. The pair of first semiconductor buffer films 153 may not be connected to each other, but rather may be physically separate from each other.

Since the first semiconductor buffer films 153 extending along the side walls of the first lower filling film recess 152R are separated from each other, the first lower semiconductor filling film 152 and the first upper semiconductor filling film 154 may be in contact with each other.

For example, the lowermost part of the first semiconductor buffer film 153 may be higher than or equal to the lower surface of the second inner gate structure INT2_GS1 on the basis of the upper surface of the first lower pattern BP1_US.

Each of the first semiconductor liner film 151, the first lower semiconductor filling film 152, the first semiconductor buffer film 153, and the first upper semiconductor filling film 154 may each include silicon-germanium. The first semiconductor liner film 151, the first lower semiconductor filling film 152, the first semiconductor buffer film 153, and the first upper semiconductor filling film 154 may each include a silicon-germanium film. The first semiconductor liner film 151, the first lower semiconductor filling film 152, the first semiconductor buffer film 153, and the first upper semiconductor filling film 154 may each be an epitaxial semiconductor film that is grown by an epitaxial process.

Each of the first semiconductor liner film 151, the first lower semiconductor filling film 152, the first semiconductor buffer film 153, and the first upper semiconductor filling film 154 may include doped p-type impurities. For example, the p-type impurities may include at least one of boron (B) and gallium (Ga).

In some embodiments, the first semiconductor buffer film 153 may be the thinnest part of the first source/drain pattern 150. For example, FIG. 2 shows that the thickest (e.g., widest) thickness of the first semiconductor buffer film 153 may be thinner than each of (i) the thickest thickness of the first semiconductor liner film 151, (ii) the thickest thickness of the first lower semiconductor filling film 152, and (iii) the thickest thickness of the first upper semiconductor filling film 154.

In FIGS. 4 to 7, a germanium fraction of the first semiconductor liner film 151 is smaller than a germanium fraction of the first lower semiconductor filling film 152. The germanium fraction of the first semiconductor liner film 151 is smaller than the germanium fraction of the first upper semiconductor filling film 154.

The germanium fraction of the first semiconductor buffer film 153 may be smaller than the germanium fraction of the first lower semiconductor filling film 152. The germanium fraction of the first semiconductor buffer film 153 may be smaller than the germanium fraction of the first upper semiconductor filling film 154.

In FIGS. 4, 6, and 7, the germanium fraction of the first upper semiconductor filling film 154 may be greater than the germanium fraction of the first lower semiconductor filling film 152.

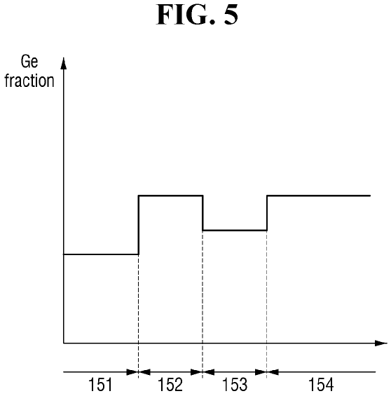

In FIG. 5, the germanium fraction of the first upper semiconductor filling film 154 may be the same as the germanium fraction of the first lower semiconductor filling film 152. In such a case, a boundary between the first lower semiconductor filling film 152 and the first upper semiconductor filling film 154 that are in contact with each other may not be distinguished. A profile of the first lower filling film recess 152R, which is a boundary between the first lower semiconductor filling film 152 and the first upper semiconductor filling film 154, may be estimated through the shape of the first semiconductor buffer film 153.

In FIGS. 4 and 5, the germanium fraction of the first semiconductor buffer film 153 may be greater than the germanium fraction of the first semiconductor liner film 151.

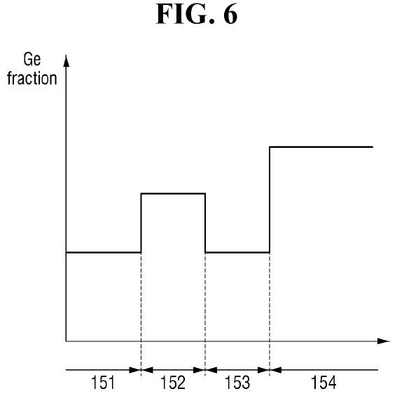

In FIG. 6, the germanium fraction of the first semiconductor buffer film 153 may be the same as the germanium fraction of the first semiconductor liner film 151.

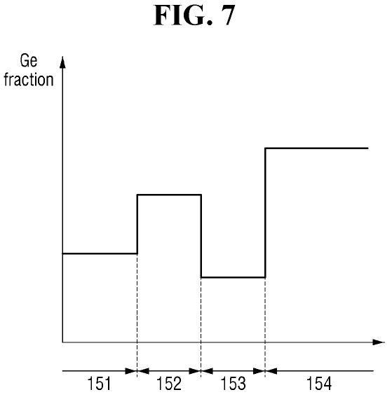

In FIG. 7, the germanium fraction of the first semiconductor buffer film 153 may be smaller than the germanium fraction of the first semiconductor liner film 151.

The concentration (/cm³) of the p-type impurities doped in the first semiconductor buffer film 153 is lower than the concentration (/cm³) of the p-type impurities doped in the first lower semiconductor filling film 152. The concentration of p-type impurities doped in the first semiconductor buffer film 153 is lower than the concentration of p-type impurities doped in the first upper semiconductor filling film 154.

The concentration of p-type impurities doped in the first semiconductor liner film 151 is lower than the concentration of p-type impurities doped in the first lower semiconductor filling film 152. The concentration of p-type impurities doped in the first semiconductor liner film 151 is lower than the concentration of p-type impurities doped in the first upper semiconductor filling film 154.

Unlike the example shown in FIGS. 4 to 7, the germanium fraction of the first semiconductor buffer film 153 may not be lower than the germanium fraction of the first lower semiconductor filling film 152 and/or the germanium fraction of the first upper semiconductor filling film 154. Even in such a case, the concentration of the p-type impurities doped in the first semiconductor buffer film 153 may be lower than the concentration of the p-type impurities doped in the first lower semiconductor filling film 152, and may be lower than the concentration of the p-type impurities doped in the first upper semiconductor filling film 154.

When the first active pattern AP1 is disposed in a NMOS formation region, the first semiconductor liner film 151, the first lower semiconductor filling film 152, the first semiconductor buffer film 153, and the first upper semiconductor filling film 154 may each contain silicon.

The first source/drain pattern 150 may include n-type impurities. The first semiconductor liner film 151, the first lower semiconductor filling film 152, the first semiconductor buffer film 153, and the first upper semiconductor filling film 154 may each include n-type impurities. For example, the n-type impurities may include at least one of phosphorus (P), arsenic (As), antimony (As), and bismuth (Bi).

The concentration of n-type impurities doped in the first semiconductor buffer film 153 is lower than the concentration of n-type impurities doped in the first lower semiconductor filling film 152. The concentration of n-type impurities doped in the first semiconductor buffer film 153 is lower than the concentration of n-type impurities doped in the first upper semiconductor filling film 154.

In the vicinity of the first sheet patterns NS1 disposed at first and/or second from above, the thickness of the first semiconductor liner film 151 and the thickness of the first lower semiconductor filling film 152 may be thin due to the influence of the first gate spacer 140. As a result, the distance between the first upper semiconductor filling film 154 and the first sheet pattern NS1 may be short. When the distance between the first upper semiconductor filling film 154 and the first sheet pattern NS1 is short, the p-type impurities doped in the first upper semiconductor filling film 154 may be easily diffused into the first sheet pattern NS1. When a large amount of p-type impurities are diffused into the first sheet pattern NS1, the performance and reliability of the semiconductor device may deteriorate due to DIBL (Drain Induced Barrier Lowering).

On the other hand, the first semiconductor buffer film 153 is disposed between (e.g., in the first direction D1) the first upper semiconductor filling film 154 and the first sheet pattern NS1 (e.g., an uppermost one of the first sheet patterns NS1), and the p-type impurities contained in the first upper semiconductor filling film 154 may be impeded or prevented from being diffused to the first sheet pattern NS1. Accordingly, the performance and reliability of the semiconductor device may be improved.

The source/drain etching stop film 185 may extend along the outer wall of the first gate spacer 140 and the profile of the first source/drain pattern 150. Although not shown, the source/drain etching stop film 185 may be disposed on the upper surface of the field insulating film 105.

From a cross-sectional point of view, the first gate capping pattern 145 may be disposed on the upper surface of the source/drain etching stop film 185. Unlike the shown example, the source/drain etching stop film 185 may extend along the side walls of the first gate capping pattern 145.

The source/drain etching stop film 185 may include a material having an etching selectivity with respect to a first interlayer insulating film 190, which will be described below. The source/drain etching stop film 185 may include, for example, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), and combinations thereof.

The first interlayer insulating film 190 may be disposed on the source/drain etching stop film 185. The first interlayer insulating film 190 may be disposed on the first source/drain pattern 150. The first interlayer insulating film 190 may not cover the upper surface of the first gate capping pattern 145. For example, the upper surface of the first interlayer insulating film 190 may be disposed on the same plane as the upper surface of the first gate capping pattern 145.

The first interlayer insulating film 190 may include, for example, at least one of silicon oxide, silicon nitride, silicon oxynitride and a low dielectric constant material. The low dielectric constant material may include, but is not limited to, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

The first source/drain contact 180 is disposed on the first source/drain pattern 150. The first source/drain contact 180 is electrically connected to the first source/drain pattern 150.

The first source/drain contact 180 passes through the first interlayer insulating film 190 and the source/drain etching stop film 185, and may be electrically connected to the first source/drain pattern 150. A part of the first source/drain contact 180 may be disposed inside the first upper semiconductor filling film 154.

The width of the first source/drain contact 180 in the first direction D1 may increase, as it goes away from the first lower pattern BP1. From a cross-sectional point of view, a part of the first interlayer insulating film 190 may be disposed between the side wall of the first source/drain contact 180 and the side wall of the first gate structure GS1.

Although the first source/drain contact 180 is shown as being a single film, this example is only for convenience of explanation and the present disclosure is not limited thereto. Unlike the shown example, the first source/drain contact 180 may have a multi-film structure including a contact plug film and a contact barrier film.

The first source/drain contact 180 may include, for example, at least one of a metal, a conductive metal nitride, a conductive metal carbide, a conductive metal oxide, a conductive metal carbonitride, and a two-dimensional (2D) material. In the semiconductor device according to some embodiments, the two-dimensional material may be a metallic material and/or a semiconductor material. The 2D material may include, but is not limited to, a 2D allotrope or a 2D compound, and may include, for example, at least one of graphene, molybdenum disulfide (MoS₂), molybdenum diselenide (MoSe₂), tungsten diselenide (WSe₂), and tungsten disulfide (WS₂). That is, since the above-mentioned 2D materials are only listed as an example, the 2D materials that may be included in the semiconductor memory device of the present disclosure are not limited by the above-mentioned materials.

A first contact silicide film 160 may be further disposed between the first source/drain contact 180 and the first source/drain pattern 150. The first contact silicide film 160 may include a metal silicide material.

A second interlayer insulating film 191 is disposed on the first interlayer insulating film 190. The second interlayer insulating film 191 may include, for example, at least one of silicon oxide, silicon nitride, silicon oxynitride, and a low dielectric constant material.

The wiring structure 205 is disposed inside the second interlayer insulating film 191. The wiring structure 205 may be electrically connected to the first source/drain contact 180. The wiring structure 205 may include a wiring line 207 and a wiring via 206.

Although the wiring line 207 and the wiring via 206 are shown to be distinguished from each other, this example is only for convenience of explanation, and the present disclosure is not limited thereto. That is, as an example, the wiring line 207 may be formed after the wiring via 206 is formed. As another example, the wiring via 206 and the wiring line 207 may be formed at the same time.

Although the wiring line 207 and the wiring via 206 are each shown as being a single film, this example is only for convenience of explanation and the present disclosure is not limited thereto. The wiring line 207 and the wiring via 206 may each include, for example, at least one of a metal, conductive metal nitride, conductive metal carbide, conductive metal oxide, conductive metal carbonitride, and a two-dimensional (2D) material.

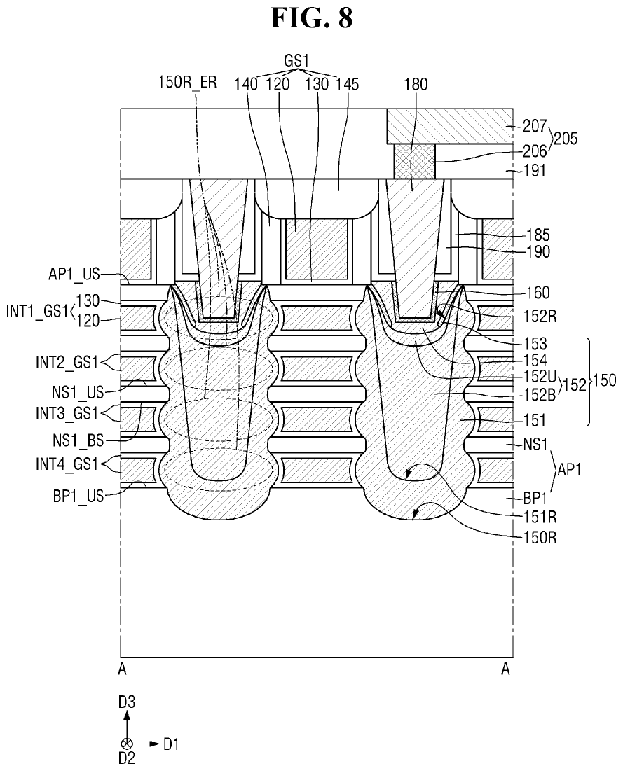

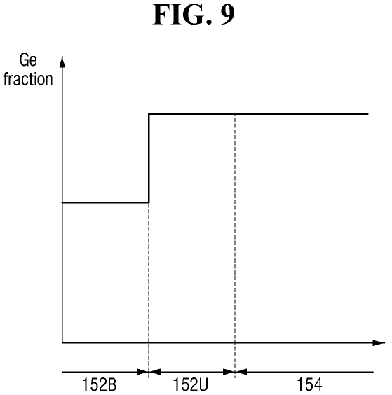

FIGS. 8 and 9 are diagrams for explaining a semiconductor device according to some embodiments. For convenience of explanation, points different from those described using FIGS. 1 to 7 will be mainly explained.

For reference, FIG. 8 may be a cross-sectional view taken along A-A of FIG. 1. FIG. 9 is a diagram for explaining the germanium fraction of the first lower semiconductor filling film and the first upper semiconductor filling film.

Referring to FIGS. 8 and 9, in the semiconductor device according to some embodiments, the first lower semiconductor filling film 152 may include a first sub-semiconductor filling film 152B and a second sub-semiconductor filling film 152U.

The second sub-semiconductor filling film 152U may be disposed on the first sub-semiconductor filling film 152B. The second sub-semiconductor filling film 152U may be disposed between the first sub-semiconductor filling film 152B and the first upper semiconductor filling film 154. The first sub-semiconductor filling film 152B may be disposed between the first semiconductor liner film 151 and the second sub-semiconductor filling film 152U.

For example, the first lower filling film recess 152R may be defined by the second sub-semiconductor filling film 152U. The second sub-semiconductor filling film 152U may include an inner side face of the first lower semiconductor filling film 152. In the semiconductor device according to some embodiments, the second sub-semiconductor filling film 152U may be in contact with the first upper semiconductor filling film 154.

The first sub-semiconductor filling film 152B and the second sub-semiconductor filling film 152U may each include a silicon-germanium film.

The germanium fraction of the first sub-semiconductor filling film 152B is different from the germanium fraction of the second sub-semiconductor filling film 152U. For example, the germanium fraction of the first sub-semiconductor filling film 152B is smaller than the germanium fraction of the second sub-semiconductor filling film 152U.

For example, the germanium fraction of the second sub-semiconductor filling film 152U may be the same as the germanium fraction of the first upper semiconductor filling film 154. Unlike the shown example, the germanium fraction of the second sub-semiconductor filling film 152U may be greater than the germanium fraction of the first upper semiconductor filling film 154.

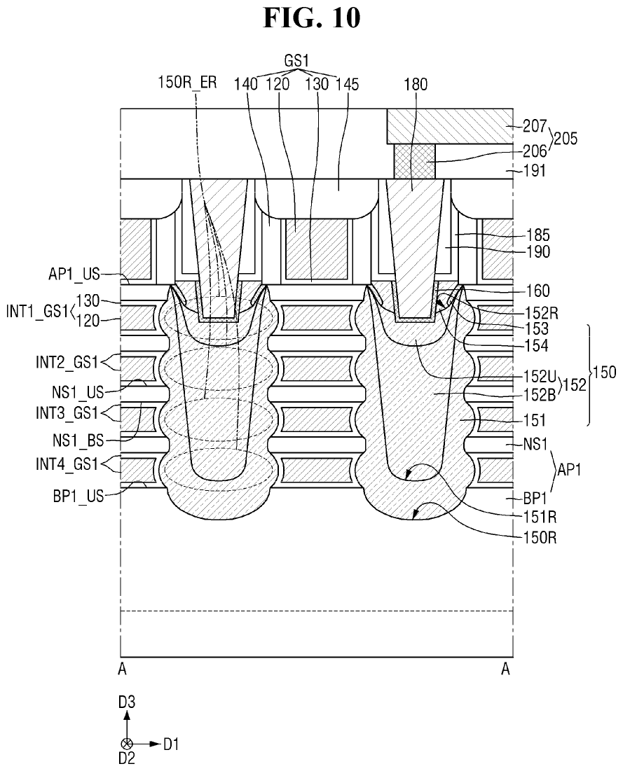

FIG. 10 is a diagram for explaining a semiconductor device according to some embodiments. For convenience of explanation, points different from those explained using FIGS. 8 and 9 will be mainly explained.

Referring to FIG. 10, in the semiconductor device according to some embodiments a part of the first source/drain contact 180 may be disposed in the first upper semiconductor filling film 154 and the second sub-semiconductor filling film 152U.

The first upper semiconductor filling film 154 and the second sub-semiconductor filling film 152U may cover a part of the side wall of the first source/drain contact 180.

For example, the lowermost part of the first semiconductor buffer film 153 may be higher than the bottom part of the first source/drain contact 180 on the basis of the upper surface of the first lower pattern BP1_US.

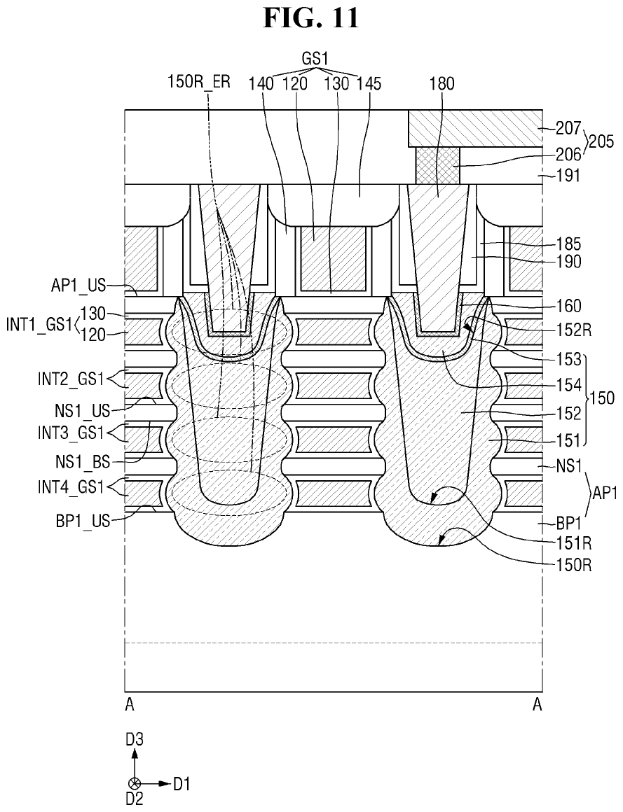

FIGS. 11 to 14 are diagrams for explaining a semiconductor device according to some embodiments. For convenience of explanation, points different from those described using FIGS. 1 to 7 will be mainly explained.

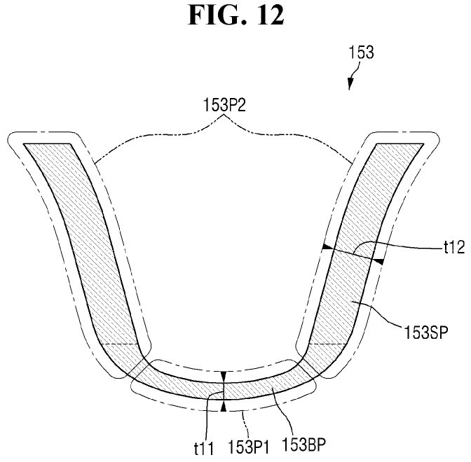

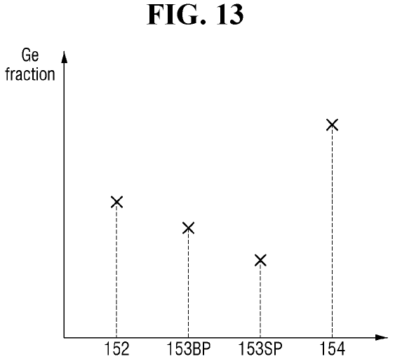

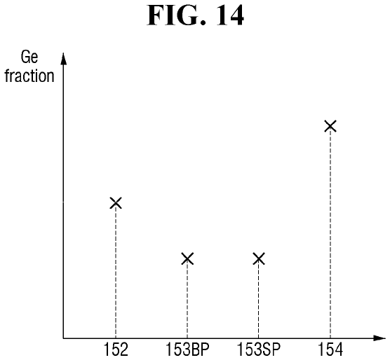

For reference, FIG. 11 is a cross-sectional view taken along a line A-A of FIG. 1. FIG. 12 is a diagram for explaining the shape of the first semiconductor buffer film of FIG. 11. FIGS. 13 and 14 are diagrams for explaining the germanium fraction of the first semiconductor buffer film, the first lower semiconductor filling film, and the first upper semiconductor filling film.

Referring to FIGS. 11 to 14, in the semiconductor device according to some embodiments, the first semiconductor buffer film 153 may extend along the profile of the first lower filling film recess 152R.

The first semiconductor buffer film 153 may separate the first upper semiconductor filling film 154 and the first lower semiconductor filling film 152. Unlike the first semiconductor buffer film 153 described using FIGS. 2 to 10, the first semiconductor buffer film 153 may not be separated into two portions from the cross-sectional point of view, but rather may extend continuously under the first source/drain contact 180.

The first semiconductor buffer film 153 may include a bottom buffer film 153BP (e.g., a bottom portion of the first semiconductor buffer film 153) and a side buffer film 153SP (e.g., a side portion of the first semiconductor buffer film 153). The side buffer film 153SP may be directly connected to (i.e., contiguous/in contact with) the bottom buffer film 153BP. The side buffer film 153SP may extend in the third direction D3 from the bottom buffer film 153BP.

A thickness t11 of the bottom buffer film 153BP may be different from a thickness t12 of the side buffer film 153SP. For example, the thickness t11 of the bottom buffer film 153BP may be smaller than the thickness t12 of the side buffer film 153SP. In FIG. 12, the first semiconductor buffer film 153 may include a first end and a second end. Between the first end of the first semiconductor buffer film 153 and the second end of the first semiconductor buffer film 153, the first semiconductor buffer film 153 may include a portion in which a thickness decreases and then increases again.

In FIGS. 13 and 14, the germanium fraction of the bottom buffer film 153BP may be smaller than the germanium fraction of the first lower semiconductor filling film 152 and the germanium fraction of the first upper semiconductor filling film 154. The germanium fraction of the side buffer film 153SP may be smaller than the germanium fraction of the first lower semiconductor filling film 152 and the germanium fraction of the first upper semiconductor filling film 154.

In FIG. 13, the germanium fraction of the bottom buffer film 153BP may be different from the germanium fraction of the side buffer film 153SP. For example, the germanium fraction of the bottom buffer film 153BP may be greater than the germanium fraction of the side buffer film 153SP.

In FIG. 14, the germanium fraction of the bottom buffer film 153BP may be the same as the germanium fraction of the side buffer film 153SP.

In the semiconductor device according to some embodiments, the first semiconductor buffer film 153 may include a first portion 153P1 extending in the first direction D1, and a second portion 153P2 extending in the third direction D3. The first portion 153P1 of the first semiconductor buffer film may be directly connected to (i.e., in contact with) the second portion 153P2 of the first semiconductor buffer film 153.

The second portion 153P2 of the first semiconductor buffer film 153 may include a part of the bottom buffer film 153BP and a side buffer film 153SP. Unlike the shown example, the bottom buffer film 153BP may be the first portion 153P1 of the first semiconductor buffer film, and the side buffer film 153SP may be the second portion 153P2 of the first semiconductor buffer film 153.

The first semiconductor buffer film 153 may have a shape of the profile of the first lower filling film recess 152R. From the cross-sectional point of view, the first portion 153P1 of the first semiconductor buffer film 153 may have a curved shape along the profile of the first lower filling film recess 152R.

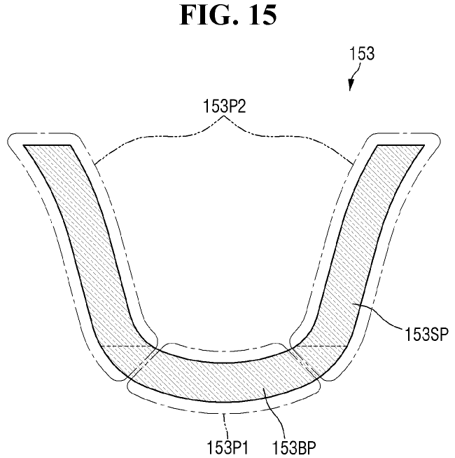

FIGS. 15 to 17 are diagrams for explaining a semiconductor device according to some embodiments, respectively. For convenience of explanation, points different from those described using FIGS. 11 to 14 will be mainly explained.

For reference, FIGS. 15 to 17 are diagrams for explaining the shape of the first semiconductor buffer film 153 of FIG. 11, respectively.

Referring to FIGS. 11 and 15, in the semiconductor device according to some embodiments, the first semiconductor buffer film 153 may conformally extend along the profile of the first lower filling film recess 152R.

The thickness of the bottom buffer film 153BP may be the same as the thickness of the side buffer film 153SP. In such a case, the germanium fraction of the bottom buffer film 153BP may be greater than the germanium fraction of the side buffer film 153SP.

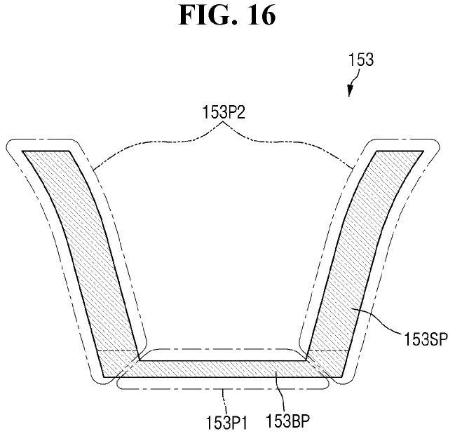

Referring to FIGS. 11 and 16, in the semiconductor device according to some embodiments, the first portion 153P1 of the first semiconductor buffer film 153 may have a planar (rather than curved) shape from the cross-sectional point of view.

For example, the lower surface of the first lower filling film recess 152R may be a plane from the cross-sectional point of view.

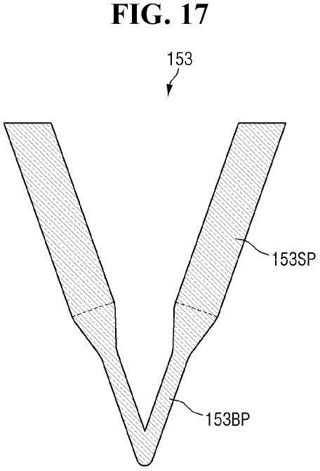

Referring to FIGS. 11 and 17, in the semiconductor device according to some embodiments, the first semiconductor buffer film 153 does not include a first portion (153P1 of FIG. 12) of the first semiconductor buffer film extending in the first direction D1.

The first semiconductor buffer film 153 may have, for example, a “V” shape. For example, the bottom buffer film 153BP may have a “V” shape. The side buffer film 153SP may extend in the third direction D3 at both ends of the V-shaped bottom buffer film 153BP.

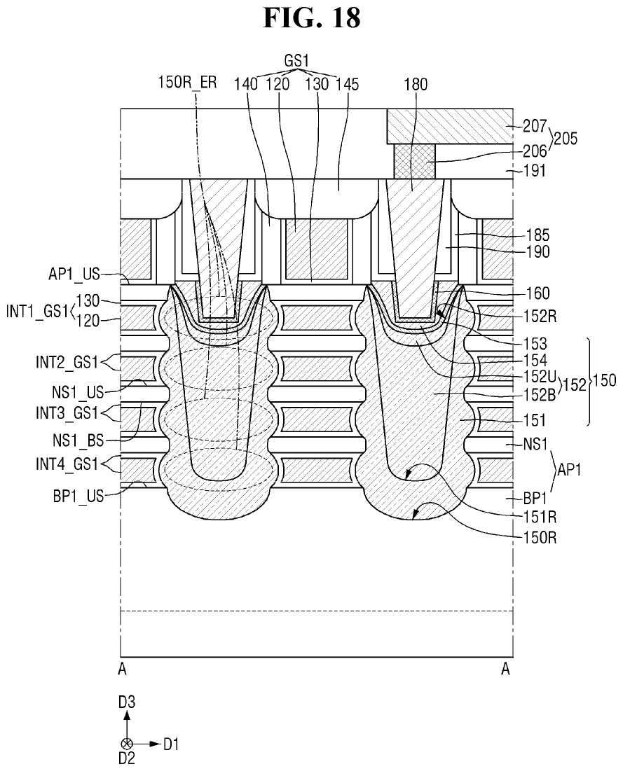

FIG. 18 is a diagram for explaining a semiconductor device according to some embodiments. For convenience of explanation, points different from those described using FIGS. 11 to 14 will be mainly explained.

Referring to FIG. 18, in the semiconductor device according to some embodiments, the first lower semiconductor filling film 152 may include a first sub-semiconductor filling film 152B and a second sub-semiconductor filling film 152U.

The second sub-semiconductor filling film 152U may be disposed between the first sub-semiconductor filling film 152B and the first semiconductor buffer film 153. The second sub-semiconductor filling film 152U may separate the first sub-semiconductor filling film 152B and the first semiconductor buffer film 153. The first sub-semiconductor filling film 152B may be disposed between the first semiconductor liner film 151 and the second sub-semiconductor filling film 152U.

The germanium fraction of the first sub-semiconductor filling film 152B is smaller than the germanium fraction of the second sub-semiconductor filling film 152U. As an example, the germanium fraction of the second sub-semiconductor filling film 152U may be the same as the germanium fraction of the first upper semiconductor filling film 154. As another example, the germanium fraction of the second sub-semiconductor filling film 152U may be greater than the germanium fraction of the first upper semiconductor filling film 154.

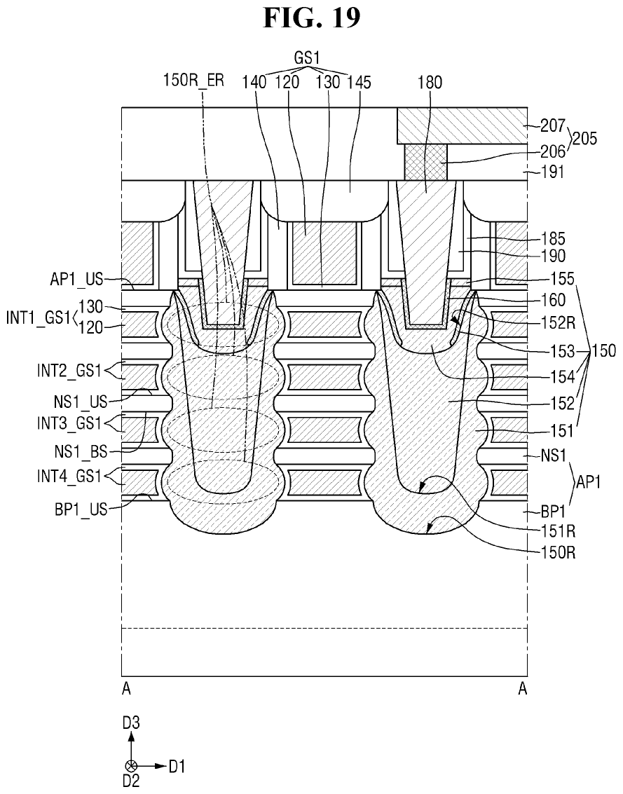

FIGS. 19 to 21 are diagrams for explaining a semiconductor device according to some embodiments, respectively. For convenience of explanation, points different from those described using FIGS. 1 to 7 will be mainly explained.

Referring to FIG. 19, in the semiconductor device according to some embodiments, the first source/drain pattern 150 may further include a semiconductor capping film 155.

The semiconductor capping film 155 may be disposed on the first upper semiconductor filling film 154. The semiconductor capping film 155 may be in contact with the first upper semiconductor filling film 154.

As an example, the semiconductor capping film 155 may include silicon. The semiconductor capping film 155 may include a silicon film.

As another example, the semiconductor capping film 155 may include silicon-germanium. The semiconductor capping film 155 may include a silicon-germanium film.

The germanium fraction of the semiconductor capping film 155 is smaller than the germanium fraction of the first upper semiconductor filling film 154. When the semiconductor capping film 155 is a silicon film, since the semiconductor capping film 155 does not contain germanium, the germanium fraction of the semiconductor capping film 155 is smaller than the germanium fraction of the first upper semiconductor filling film 154.

When the semiconductor capping film 155 includes silicon-germanium, the germanium fraction of the semiconductor capping film 155 may be, but is not limited to being, smaller than the germanium fraction of the first semiconductor liner film 151.

The semiconductor capping film 155 may include, but is not limited to, doped p-type impurities.

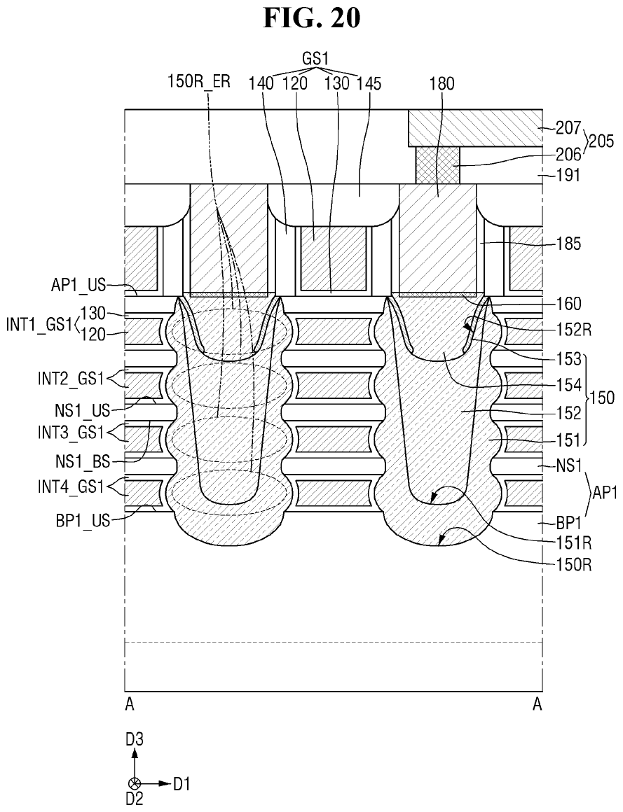

Referring to FIG. 20, in the semiconductor device according to some embodiments a side wall of the first source/drain contact 180 may be in contact with the source/drain etching stop film 185.

From the cross-sectional point of view, the first interlayer insulating film (190 of FIG. 2) may not be disposed between the side wall of the first source/drain contact 180 and the side wall of the first gate structure GS1.

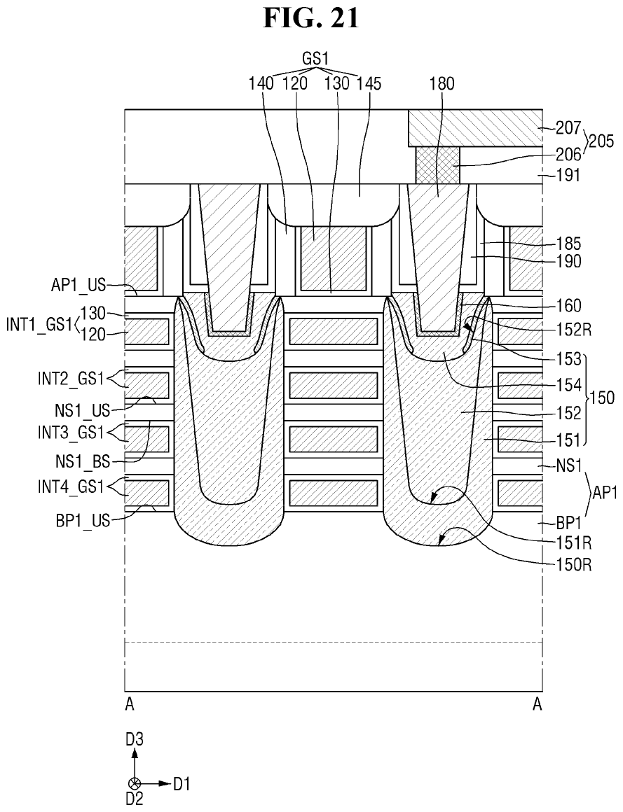

Referring to FIG. 21, in the semiconductor device according to some embodiments, the first source/drain recess 150R does not include the plurality of first width expansion regions (150R_ER of FIG. 2).

The side wall of the first source/drain recess 150R does not have a wavy shape. The upper part of the side wall of the first source/drain recess 150R may decrease in the width in the first direction D1, as it goes away from the first lower pattern BP1.

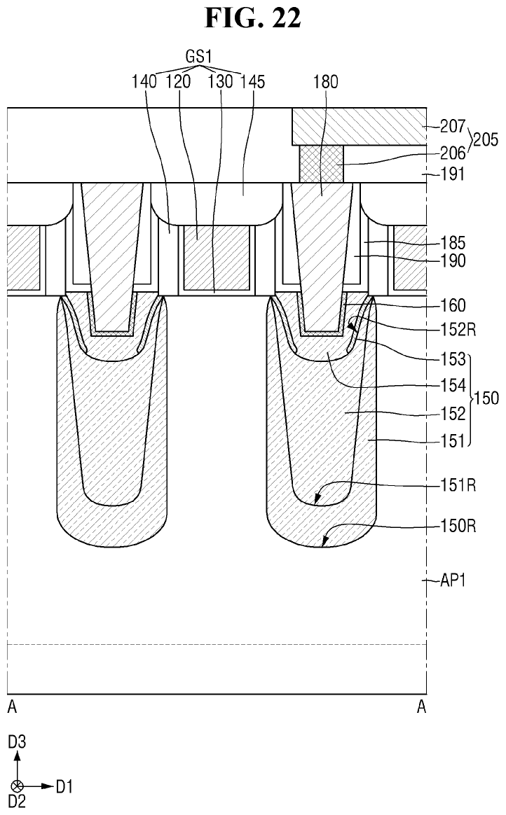

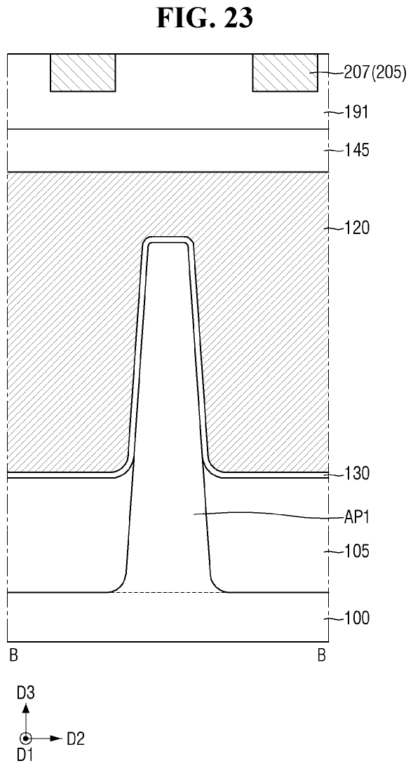

FIGS. 22 and 23 are diagrams for explaining a semiconductor device according to some embodiments. For convenience of explanation, points different from those described using FIGS. 1 to 7 will be mainly explained.

Referring to FIGS. 22 and 23, in the semiconductor device according to some embodiments, the first active pattern AP1 does not include the first sheet pattern (NS1 of FIG. 2).

The first active pattern AP1 may be a fin-shaped pattern. The first active pattern AP1, which is a fin-shaped pattern, may be used as a channel region of a transistor including the first gate electrode 120.

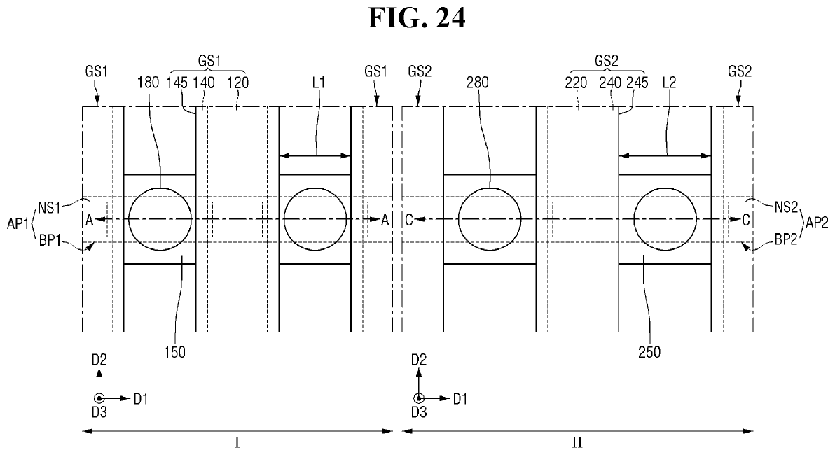

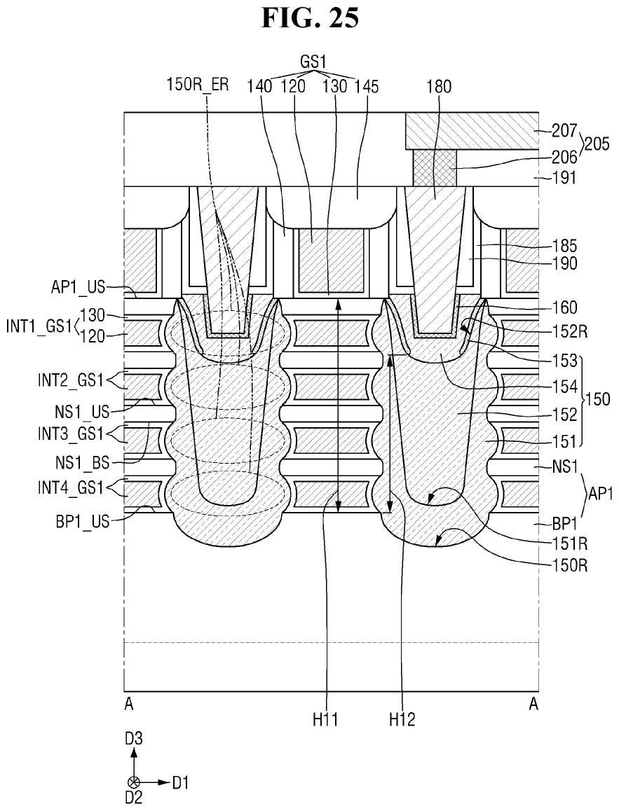

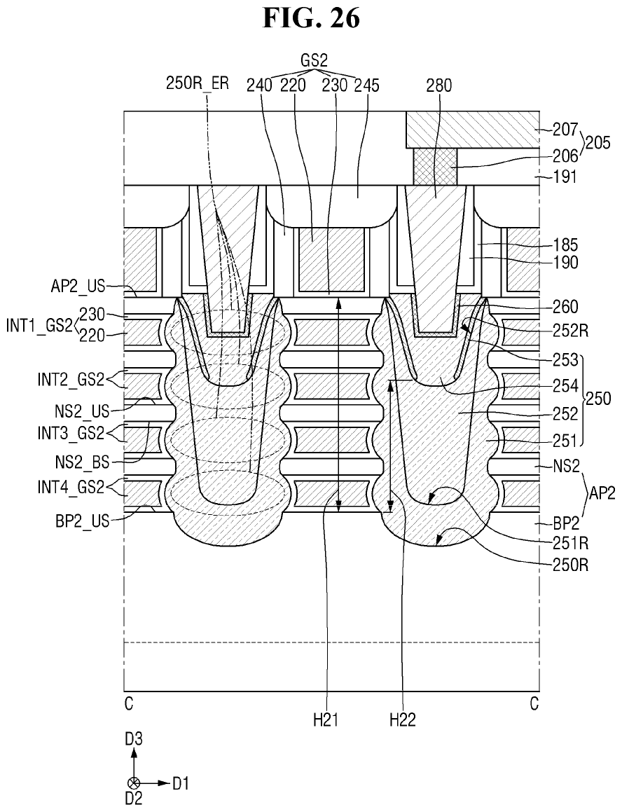

FIG. 24 is an example plan view for explaining a semiconductor device according to some embodiments. FIG. 25 is a cross-sectional view taken along a line A-A of FIG. 24. FIG. 26 is a cross-sectional view taken along a line C-C of FIG. 24.

For reference, since FIG. 25 is substantially the same as FIG. 2 except for the height indication for explaining a position of the first semiconductor buffer film 153, repeated content will not be provided. That is, the following description will focus on the content about the second region II of FIG. 24.

Although FIG. 25 is shown as being the same as FIG. 2, the cross-sectional view taken along line A-A of FIG. 24 may be the same as one of FIGS. 8, 10, 11, and 18. In such a case, the cross-sectional view taken along C-C of FIG. 24 may vary as the cross-sectional view taken along A-A of FIG. 24 changes.

Referring to FIGS. 24 to 26, the semiconductor device according to some embodiments may include a first active pattern AP1, a plurality of first gate structures GS1, a first source/drain pattern 150, a second active pattern AP2, a plurality of second gate structures GS2, and a second source/drain pattern 250.

The substrate 100 may include a first region I and a second region II. If the first region I is a PMOS formation region, the second region II may be a PMOS formation region.

The first active pattern AP1, the plurality of first gate structures GS1, and the first source/drain pattern 150 are disposed in the first region I of the substrate 100. The second active pattern AP2, the plurality of second gate structures GS2, and the second source/drain pattern 250 are disposed in the second region II of the substrate 100.

The second active pattern AP2 may include a second lower pattern BP2 and a plurality of second sheet patterns NS2. The plurality of second sheet patterns NS2 are disposed on the upper surface BP2_US of the second lower pattern BP2. The second sheet pattern NS2 includes an upper surface NS2_US and a lower surface NS2_BS that are opposite to each other in the third direction D3. The second lower pattern BP2 and the second sheet pattern NS2 may each include one of silicon or germanium which is an elemental semiconductor material, a group IV-IV compound semiconductor, or a group III-V compound semiconductor. In the semiconductor device according to some embodiments, the second lower pattern BP2 may be a silicon lower pattern including silicon, and the second sheet pattern NS2 may be a silicon sheet pattern including silicon. The upper surface AP2_US of the second active pattern AP2 may be the upper surface of the second sheet pattern NS2 disposed on the uppermost level/part of the plurality of second sheet patterns NS2.

The description of the second active pattern AP2 may be substantially the same as the description of the first active pattern AP1.

A plurality of second gate structures GS2 may be disposed on the substrate 100. The second gate structure GS2 may be disposed on the second active pattern AP2. The second gate structure GS2 may intersect the second active pattern AP2. The second gate structure GS2 may intersect the second lower pattern BP2. The second gate structure GS2 may wrap around each second sheet pattern NS2. The second gate structure GS2 may include a plurality of inner gate structures INT1_GS2, INT2_GS2, INT3_GS2 and INT4_GS2 disposed between the second sheet patterns NS2 adjacent in the third direction D3, and between the second lower pattern BP2 and the second sheet pattern NS2. The second gate structure GS2 may include, for example, a second gate electrode 220, a second gate insulating film 230, a second gate spacer 240, and a second gate capping pattern 245.

The description of the second gate structure GS2 may be analogous to (e.g., substantially the same as) the description of the first gate structure GS1.

A first distance L1 between the first gate structures GS1 adjacent in the first direction D1 may be different from a second distance L2 between the second gate structures GS2 adjacent in the first direction D1. For example, the first distance L1 may be smaller than the second distance L2.

The second source/drain pattern 250 may be formed on the second active pattern AP2. The second source/drain pattern 250 may be formed on the second lower pattern BP2. The second source/drain pattern 250 may be electrically connected to the second sheet pattern NS2. The second source/drain pattern 250 may be included in the source/drain of a transistor that uses the second sheet pattern NS2 as a channel region.

The second source/drain pattern 250 may be disposed in the second source/drain recess 250R. The second source/drain recess 250R may include a plurality of second width expansion regions 250R_ER. A lower surface of the second source/drain recess 250R may be defined by the second lower pattern BP2. A side wall of the second source/drain recess 250R may be defined by the second sheet pattern NS2 and the inner gate structures INT1_GS2, INT2_GS2, INT3_GS2, and INT4_GS2.

The second source/drain pattern 250 may be in contact with the second gate insulating film 230 and the second lower pattern BP2 of the inner gate structures INT1_GS2, INT2_GS2, INT3_GS2, and INT4_GS2.

The second source/drain pattern 250 may include a second semiconductor liner film 251, a second lower semiconductor filling film 252, a second semiconductor buffer film 253, and a second upper semiconductor filling film 254.

The second semiconductor liner film 251 may be continuously formed along the second source/drain recess 250R. The second semiconductor liner film 251 may extend along the side wall of the second source/drain recess 250R and the lower surface of the second source/drain recess 250R. The first semiconductor liner film 151 may define a first liner recess 151R.

The second lower semiconductor filling film 252 may be disposed on the second semiconductor liner film 251. The second lower semiconductor filling film 252 may define a second lower filling film recess 252R.

The second upper semiconductor filling film 254 may be disposed on the second lower semiconductor filling film 252. The second lower semiconductor filling film 252 may be disposed between the second upper semiconductor filling film 254 and the second semiconductor liner film 251.

The second semiconductor buffer film 253 may be disposed on the second lower semiconductor filling film 252. The second semiconductor buffer film 253 may be disposed between the second lower semiconductor filling film 252 and the second upper semiconductor filling film 254. The second semiconductor buffer film 253 and the second upper semiconductor filling film 254 may fill the second lower filling film recess 252R.

The description of the second semiconductor liner film 251, the second lower semiconductor filling film 252, the second semiconductor buffer film 253, and the second upper semiconductor filling film 254 may be analogous to (e.g., substantially the same as) the description of the first semiconductor liner film 151, the first lower semiconductor filling film 152, the first semiconductor buffer film 153 and the first upper semiconductor filling film 154.

A height H11 from the upper surface BP1_US of the first lower pattern BP1 to the upper surface AP1_US of the first active pattern AP1 may be the same as a height H21 from the upper surface BP2_US of the second lower pattern BP2 to the upper surface AP2_US of the second active pattern AP2.

A height H12 from the upper surface BP1_US of the first lower pattern BP1 to the lowermost part of the first semiconductor buffer film 153 may be greater than or equal to a height H22 from the upper surface BP2_US of the second lower pattern BP2 to the lowermost part of the second semiconductor buffer film 253.

A second source/drain contact 280 is disposed on the second source/drain pattern 250. The second source/drain contact 280 is electrically connected to the second source/drain pattern 250. A second contact silicide film 260 may be further disposed between the second source/drain contact 280 and the second source/drain pattern 250.

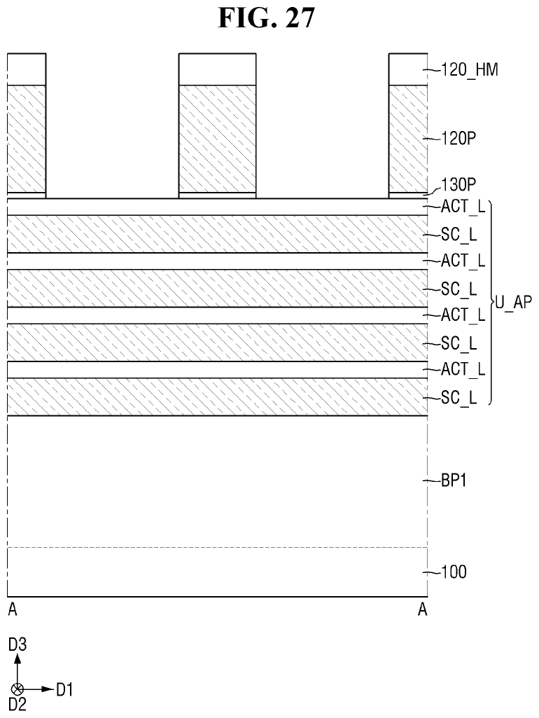

FIGS. 27 to 36 are intermediate step diagrams for explaining a method for fabricating a semiconductor device according to some embodiments. For reference, FIGS. 27 to 36 may be cross-sectional views taken along A-A of FIG. 1.

Referring to FIG. 27, the first lower pattern BP1 and the upper pattern structure U_AP may be formed on the substrate 100.

The upper pattern structure U_AP may be disposed on the first lower pattern BP1. The upper pattern structure U_AP may include a plurality of sacrificial patterns SC_L and a plurality of active patterns ACT_L, which are alternately stacked on the first lower pattern BP1.

For example, the sacrificial pattern SC_L may include a silicon-germanium film. The active pattern ACT_L may include a silicon film.

Subsequently, the dummy gate insulating film 130P, the dummy gate electrode 120P, and the dummy gate capping film 120_HM may be formed on the upper pattern structure U_AP. The dummy gate insulating film 130P may include, for example, but is not limited to, silicon oxide. The dummy gate electrode 120P may include, for example, but is not limited to, polysilicon. The dummy gate capping film 120_HM may include, for example, but is not limited to, silicon nitride.

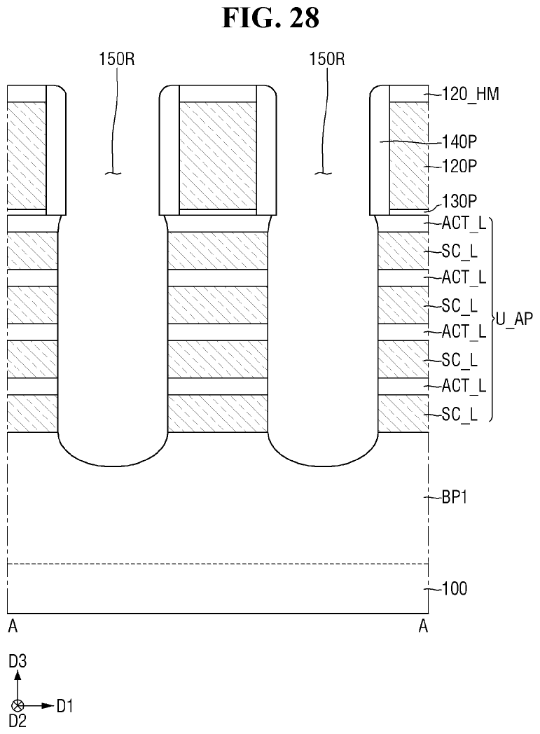

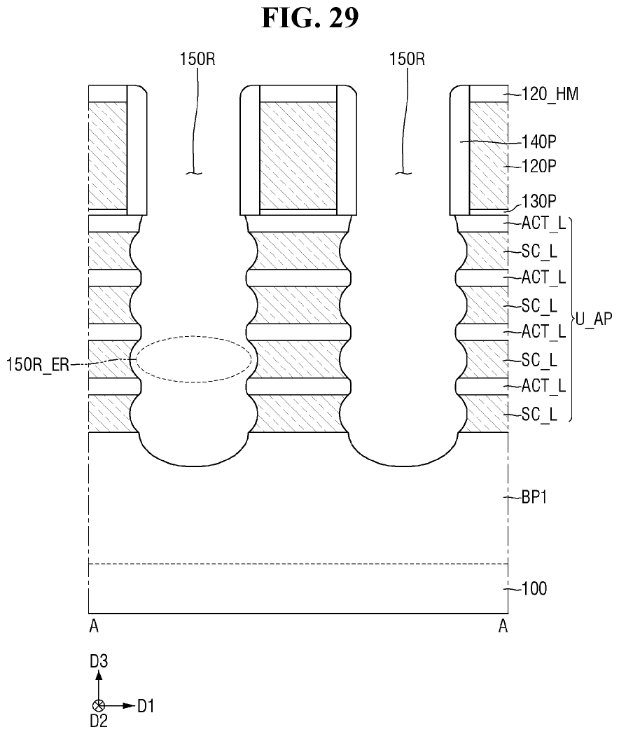

Referring to FIGS. 28 and 29, pre-gate spacers 140P may be formed on the side walls of the dummy gate electrode 120P.

The first source/drain recess 150R may be formed in the upper pattern structure U_AP, by using the dummy gate electrode 120P and the pre-gate spacer 140P as masks.

A part of the first source/drain recess 150R may be formed in the first lower pattern BP1. A lower surface of the first source/drain recess 150R may be defined by the first lower pattern BP1.

After forming the first source/drain recess 150R as shown in FIG. 28, the sacrificial pattern SC_L may be additionally etched. Therefore, the first width expansion region 150R_ER of the first source/drain recess 150R may be formed.

The first source/drain recess 150R may include a plurality of first width expansion regions 150R_ER. The side wall of the first source/drain recess 150R may have a wavy shape. However, the method for fabricating the first source/drain recess 150R including the plurality of first width expansion regions 150R_ER is not limited to the above-described method.

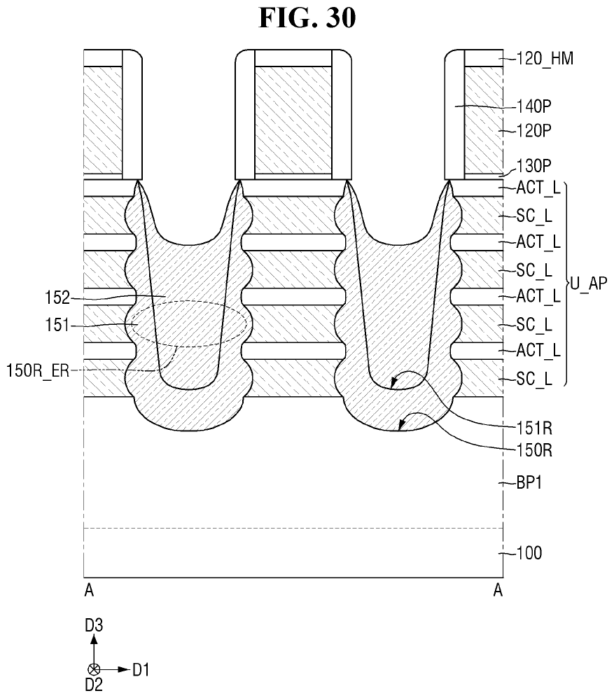

Referring to FIG. 30, the first semiconductor liner film 151 is formed on the first lower pattern BP1.

The first semiconductor liner film 151 may be formed along the profile of the first source/drain recess 150R. The first semiconductor liner film 151 may define a liner recess 151R.

The first lower semiconductor filling film 152 may be formed on the first semiconductor liner film 151. The first lower semiconductor filling film 152 may be formed along the liner recess 151R.

The first semiconductor liner film 151 and the first lower semiconductor filling film 152 may be formed using an epitaxial growth method.

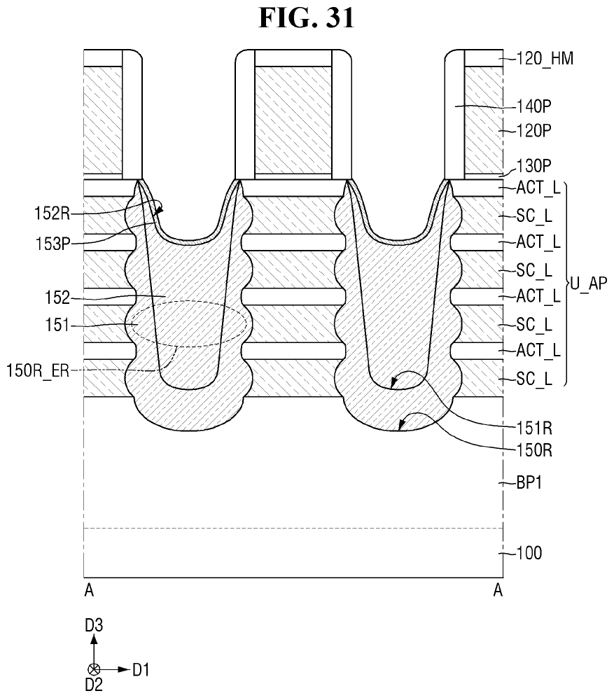

Referring to FIG. 31, a pre-semiconductor buffer film 153P may be formed on the first lower semiconductor filling film 152.

The pre-semiconductor buffer film 153P may be formed along the profile of the first lower filling film recess 152R defined by the first lower semiconductor filling film 152. The germanium fraction of the pre-semiconductor buffer film 153P may be smaller than the germanium fraction of the first lower semiconductor filling film 152.

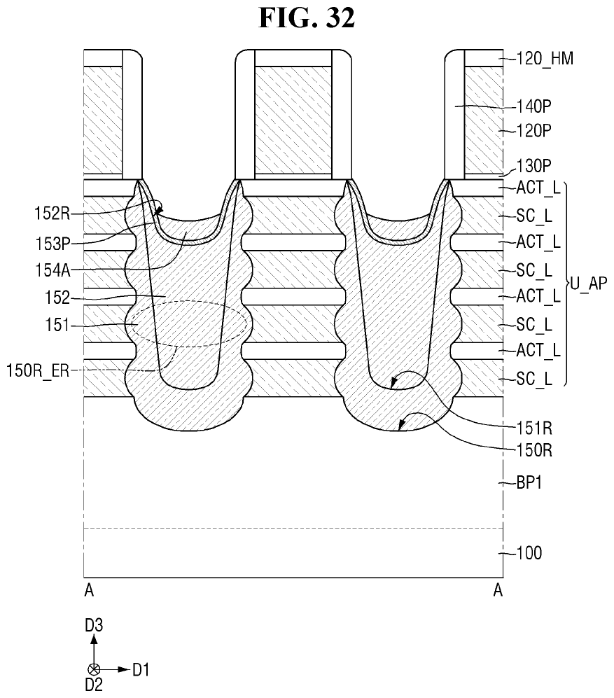

Referring to FIG. 32, a pre-upper semiconductor filling film 154A may be formed on the pre-semiconductor buffer film 153P.

The pre-upper semiconductor filling film 154A may partially fill the first lower filling film recess 152R in which the pre-semiconductor buffer film 153P is formed. The germanium fraction of the pre-upper semiconductor filling film 154A may be greater than the germanium fraction of the pre-semiconductor buffer film 153P.

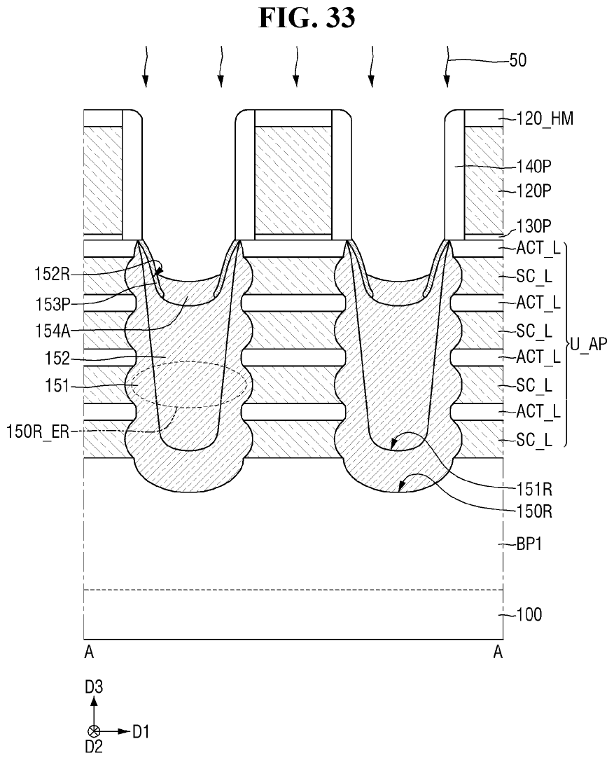

Referring to FIGS. 32 and 33, an annealing process 50 may proceed.

The pre-semiconductor buffer film 153P may be mixed with the pre-upper semiconductor filling film 154A and the first lower semiconductor filling film 152 through the annealing process 50. While the annealing process 50 is being performed, the first semiconductor buffer films 153 separated from each other may be formed.

Unlike the shown example, as an example, the thickness of a part of the pre-semiconductor buffer film 153P may be thinned without separating the pre-semiconductor buffer film 153P into two spaced-apart portions, while the annealing process 50 is being performed. Therefore, the first semiconductor buffer film 153 as shown in FIG. 11 may be formed.

As another example, while the annealing process 50 is being performed, the germanium fraction of a part of the pre-semiconductor buffer film 153P may become higher than the germanium fraction of the remaining part of the pre-semiconductor buffer film 153P. A part of the germanium fraction of the pre-upper semiconductor filling film 154A and/or the first lower semiconductor filling film 152 is diffused into the pre-semiconductor buffer film 153P, and the germanium fraction of a part of the pre-semiconductor buffer film 153P may be increased.

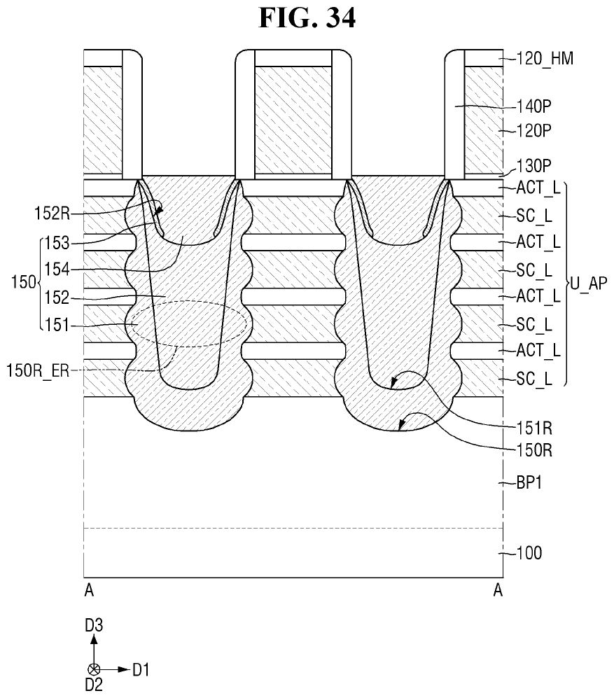

Referring to FIGS. 33 and 34, an additional semiconductor filling film may be formed on the pre-upper semiconductor filling film 154A.

Accordingly, the first upper semiconductor filling film 154 may be formed in the first lower filling film recess 152R. The first semiconductor buffer film 153 may be formed between the first lower semiconductor filling film 152 and the first upper semiconductor filling film 154.

The first source/drain pattern 150 including the first semiconductor liner 151, the first lower semiconductor filling film 152, the first semiconductor buffer film 153, and the first upper semiconductor filling film 154 may be formed in the first source/drain recess 150R.

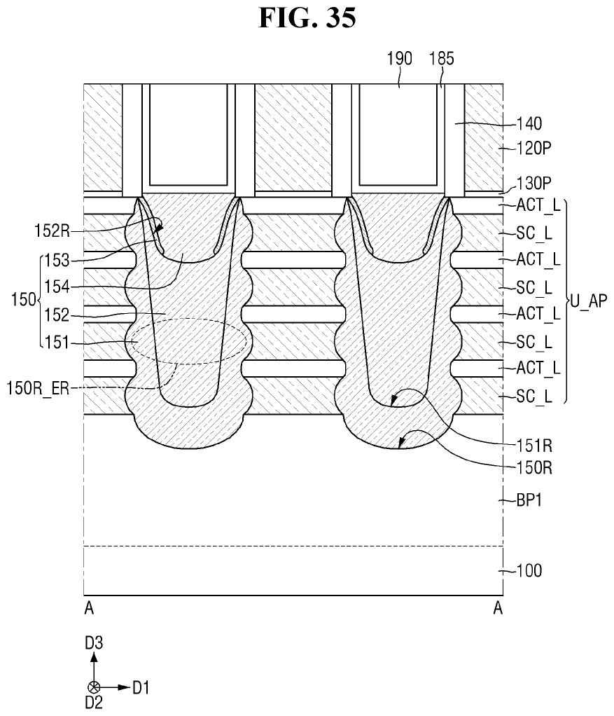

Referring to FIG. 35, the source/drain etching stop film 185 and the first interlayer insulating film 190 are sequentially formed on the first source/drain pattern 150.

Subsequently, a part of the first interlayer insulating film 190, a part of the source/drain etching stop film 185, and the dummy gate capping film 120_HM are removed to expose the upper surface of the dummy gate electrode 120P. The first gate spacer 140 may be formed, while the upper surface of the dummy gate electrode 120P is being exposed.

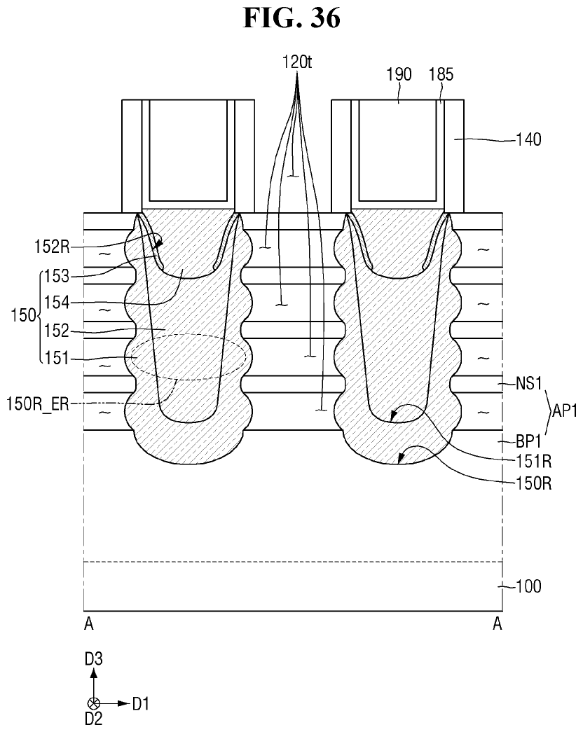

Referring to FIGS. 35 and 36, the dummy gate insulating film 130P and the dummy gate electrode 120P may be removed to expose the upper pattern structure U_AP between the first gate spacers 140.

Thereafter, the sacrificial pattern SC_L may be removed to form the first sheet pattern NS1. The first sheet pattern NS1 is electrically connected to the first source/drain pattern 150. As a result, the first active pattern AP1 including the first lower pattern BP1 and the first sheet pattern NS1 is formed.

Furthermore, the sacrificial pattern SC_L is removed to form a gate trench 120t between the first gate spacers 140. When the sacrificial pattern SC_L is removed, a part of the first source/drain pattern 150 may be exposed.

Next, referring to FIG. 2, the first gate insulating film 130 and the first gate electrode 120 may be formed in the gate trench 120t. Additionally, a first gate capping pattern 145 may be formed.

In concluding the detailed description, those skilled in the art will appreciate that many variations and modifications may be made to the example embodiments without substantially departing from the scope of the invention. Therefore, the disclosed example embodiments of the invention are used in a generic and descriptive sense only and not for purposes of limitation.

What is claimed is:

1. A semiconductor device comprising:
an active pattern extending in a first direction;
a plurality of gate structures on the active pattern and spaced apart from each other in the first direction; and
a source/drain pattern between adjacent ones of the gate structures;
wherein the source/drain pattern includes a semiconductor liner film in contact with the active pattern, a lower semiconductor filling film on the semiconductor liner film, an upper semiconductor filling film on the lower semiconductor filling film, and a semiconductor buffer film between the lower semiconductor filling film and the upper semiconductor filling film,
wherein each of the semiconductor liner film, the lower semiconductor filling film, the upper semiconductor filling film, and the semiconductor buffer film includes silicon-germanium,
wherein a germanium fraction of the semiconductor buffer film is smaller than a germanium fraction of the upper semiconductor filling film and a germanium fraction of the lower semiconductor filling film,
wherein the semiconductor buffer film and the upper semiconductor filling film are in a lower filling film recess defined by the lower semiconductor filling film, and
wherein the semiconductor buffer film extends along a part of the lower filling film recess.

2. The semiconductor device of claim 1,
wherein the upper semiconductor filling film is in contact with the lower semiconductor filling film.

3. The semiconductor device of claim 2,
wherein the semiconductor buffer film extends along a side wall of the lower filling film recess, and does not extend along a lower surface of the lower filling film recess.

4. The semiconductor device of claim 1,
wherein a germanium fraction of the semiconductor liner film is smaller than the germanium fraction of the upper semiconductor filling film and the germanium fraction of the lower semiconductor filling film.

5. The semiconductor device of claim 1,
wherein the germanium fraction of the upper semiconductor filling film is greater than or equal to the germanium fraction of the lower semiconductor filling film.

6. The semiconductor device of claim 1,
wherein the lower semiconductor filling film includes a first lower semiconductor filling film and a second lower semiconductor filling film,
wherein the first lower semiconductor filling film is between the semiconductor liner film and the second lower semiconductor filling film, and
wherein a germanium fraction of the first lower semiconductor filling film is smaller than a germanium fraction of the second lower semiconductor filling film.

7. The semiconductor device of claim 6,
wherein the germanium fraction of the second lower semiconductor filling film is equal to the germanium fraction of the upper semiconductor filling film.

8. The semiconductor device of claim 1,
wherein the source/drain pattern further includes a semiconductor capping film on the upper semiconductor filling film, and
wherein a germanium fraction of the semiconductor capping film is smaller than the germanium fraction of the upper semiconductor filling film.

9. The semiconductor device of claim 1,
wherein the active pattern includes a lower pattern extending in the first direction, and a plurality of sheet patterns spaced apart from the lower pattern in a second direction perpendicular to the first direction, and
wherein the semiconductor liner film is in contact with the lower pattern and each of the sheet patterns.

10. A semiconductor device comprising:
an active pattern that includes a lower pattern extending in a first direction, and a plurality of sheet patterns spaced apart from the lower pattern in a second direction perpendicular to the first direction;
a plurality of gate structures that are on the lower pattern and spaced apart from each other in the first direction, and include a gate electrode and a gate insulating film; and
a source/drain pattern between adjacent ones of the gate structures,
wherein the source/drain pattern includes a semiconductor liner film in contact with the lower pattern and the sheet patterns, a lower semiconductor filling film on the semiconductor liner film, an upper semiconductor filling film on the lower semiconductor filling film, and a semiconductor buffer film between the lower semiconductor filling film and the upper semiconductor filling film,
wherein the semiconductor liner film, the lower semiconductor filling film, the upper semiconductor filling film, and the semiconductor buffer film each include silicon-germanium,
wherein a germanium fraction of the semiconductor buffer film is smaller than a germanium fraction of the upper semiconductor filling film and a germanium fraction of the lower semiconductor filling film,
wherein the semiconductor buffer film extends along a profile of a lower filling film recess defined by the lower semiconductor filling film,
wherein the semiconductor buffer film includes a bottom portion, and a side portion extending in the second direction from the bottom portion, and
wherein a germanium fraction of the side portion is different from a germanium fraction of the bottom portion.

11. The semiconductor device of claim 10,
wherein the germanium fraction of the side portion is smaller than the germanium fraction of the bottom portion.

12. The semiconductor device of claim 10,
wherein a thickness of the side portion is greater than a thickness of the bottom portion.

13. The semiconductor device of claim 10,
wherein the germanium fraction of the upper semiconductor filling film is greater than or equal to the germanium fraction of the lower semiconductor filling film.

14. The semiconductor device of claim 10,
wherein the lower semiconductor filling film includes a first lower semiconductor filling film and a second lower semiconductor filling film,
wherein the first lower semiconductor filling film is between the semiconductor liner film and the second lower semiconductor filling film, and
wherein a germanium fraction of the first lower semiconductor filling film is smaller than a germanium fraction of the second lower semiconductor filling film.

15. The semiconductor device of claim 14,
wherein the germanium fraction of the second lower semiconductor filling film is equal to the germanium fraction of the upper semiconductor filling film.

16. The semiconductor device of claim 10,
wherein the semiconductor buffer film has a V-shape.

17. The semiconductor device of claim 10,
wherein the semiconductor buffer film includes a first portion extending in the first direction, and a second portion extending in the second direction.

18. A semiconductor device comprising:
an active pattern that includes a lower pattern extending in a first direction, and a plurality of sheet patterns spaced apart from the lower pattern in a second direction perpendicular to the first direction;
a plurality of gate structures that are on the lower pattern and spaced apart from each other in the first direction, and include a gate electrode and a gate insulating film; and
a source/drain pattern between adjacent ones of the gate structures,
wherein the source/drain pattern includes a semiconductor liner film in contact with the lower pattern and the sheet patterns, a lower semiconductor filling film on the semiconductor liner film, an upper semiconductor filling film on the lower semiconductor filling film, and a semiconductor buffer film between the lower semiconductor filling film and the upper semiconductor filling film,
wherein the semiconductor liner film, the lower semiconductor filling film, the upper semiconductor filling film, and the semiconductor buffer film each include silicon-germanium,
wherein a germanium fraction of the semiconductor buffer film is smaller than a germanium fraction of the upper semiconductor filling film and a germanium fraction of the lower semiconductor filling film,
wherein the semiconductor buffer film extends along a profile of a lower filling film recess defined by the lower semiconductor filling film,
wherein the semiconductor buffer film includes a bottom portion, and a side portion extending in the second direction from the bottom portion, and
wherein a thickness of the side portion is greater than a thickness of the bottom portion.

19. The semiconductor device of claim 18,
wherein the germanium fraction of the upper semiconductor filling film is greater than the germanium fraction of the lower semiconductor filling film.

20. The semiconductor device of claim 18,
wherein the lower semiconductor filling film includes a first lower semiconductor filling film and a second lower semiconductor filling film,
wherein the first lower semiconductor filling film is between the semiconductor liner film and the second lower semiconductor filling film, and
wherein a germanium fraction of the first lower semiconductor filling film is smaller than a germanium fraction of the second lower semiconductor filling film.
